(19) United States
(12) Patent Application Publication
(10) Pub. No.: US 2026/0246241 A1
(43) Pub. Date: Aug. 20, 2026

(54) SURFACE-EMITTING LASER ARRAY

(71) Applicant: SONY SEMICONDUCTOR SOLUTIONS CORPORATION, KANAGAWA (JP)

(72) Inventors: TOSHIYUKI KITAI, KUMAMOTO (JP); KOTA TOKUDA, KANAGAWA (JP)

(21) Appl. No.: 19/155,974

(22) PCT Filed: Jan. 18, 2024
(86) PCT No.: PCT/JP2024/001253

§ 371 Date: Aug. 13, 2025

(30) Foreign Application Priority Data
Mar. 9, 2023 (JP) 2023-036702

(51) Int. Cl. H01S 5/42

(52) U.S. Cl. CPC H01S 5/423

(57) ABSTRACT

Provided is a surface-emitting laser array capable of suppressing in-plane variation in light emission intensity while suppressing an increase in the scale of the array and suppressing the occurrence of vignetting. The surface-emitting laser array according to the present technique includes a first region in which a plurality of surface-emitting lasers are disposed in an array, and a second region surrounding the first region. Among a first part and a second part, which are adjacent in an in-plane direction, of a base structure including a substrate, the first part is included in the first region and the second part is included in the second region. An average resistance of the first part is lower than an average resistance of the second part.

According to the surface-emitting laser array of the present technique, a surface-emitting laser array can be provided which is capable of suppressing in-plane variation in light emission intensity while suppressing an increase in the scale of the array and suppressing the occurrence of vignetting.

### TECHNICAL FIELD

The technique according to the present disclosure (hereinafter also referred to as the “present technique”) relates to a surface-emitting laser array.

### BACKGROUND ART

A conventional surface-emitting laser array in which a plurality of surface-emitting lasers are arranged in an array is known.

Some conventional surface-emitting laser arrays are intended to suppress in-plane variation in light emission intensity.

For example, in the surface-emitting laser array described in PTL 1, the density at which surface-emitting lasers are disposed is lower in an outer peripheral part than that in an inner peripheral part.

For example, the surface-emitting laser array described in PTL 2 has a layered electrode structure including first and second upper electrodes in which outer peripheral parts thereof are layered with an insulating film therebetween, and inner peripheral parts thereof are layered directly on each other.

### CITATION LIST

### Patent Literature

### PTL 1

No. JP 2017-98532A

### PTL 2

No. JP 2017-216285A

### SUMMARY

### Technical Problem

For example, with the surface-emitting laser array described in PTL 1, it is necessary to increase the interval between surface-emitting lasers gradually with proximity to the outer peripheral side, and this risks increasing the scale of the array.

For example, with the surface-emitting laser array described in PTL 2, an opening serving as an outlet is defined by the stated layered electrode structure of the surface-emitting laser disposed in the outer peripheral part, and this may have a risk that vignetting will occur.

Accordingly, a main object of the present technique is to provide a surface-emitting laser array capable of suppressing in-plane variation in light emission intensity while suppressing an increase in the scale of the array and suppressing the occurrence of vignetting.

### Solution to Problem

The present technique provides a surface-emitting laser array including:
a first region in which a plurality of surface-emitting lasers are disposed in an array; and
a second region that surrounds the first region, wherein
among a first part and a second part, which are adjacent in an in-plane direction, of a base structure including a substrate,, the first part is included in the first region and the second part is included in the second region, and
an average resistance of the first part is lower than an average resistance of the second part.

The first part may have a low resistance region in which the average resistance of the first part is lower than the average resistance of the second part, and/or the second part may have a high-resistance region in which the average resistance of the second part is higher than the average resistance of the first part.

When the first part has the low resistance region, the low-resistance region may be an impurity region, and when the second part has the high resistance region, the high resistance region may be an insulating region or a semi-insulating region.

The first part may have the low resistance region, and the low-resistance region may be an impurity region provided within the substrate.

The second part may have the high resistance region, and the high-resistance region may be an ion implantation region provided within the substrate.

Each of the plurality of surface-emitting lasers may have a resonator disposed on the substrate, the second part may have the high-resistance region, and the high-resistance region may be provided on a surface of the substrate on a side, where the resonator is located, in the second part.

The resonator may include a first structure disposed on the substrate and including a first reflector, an active layer disposed on the first structure, and a second structure disposed on the active layer and including a second reflector; the second part may include at least part of the first structure in a layering direction thereof, provided on a surface of the substrate on a side, where the resonator is located; and the high-resistance region may be an ion implantation region provided within the at least part of the first structure.

The high resistance region may be an insulating region provided on a surface of the substrate on a side, where the resonator is located, in the second part.

Each of the plurality of surface-emitting lasers may have a resonator disposed on the substrate; an electrode may be provided on a surface of the substrate on an opposite side to the side, where the resonator is located, in the first part; the second part may have the high resistance region; and the high-resistance region may be provided on a surface of the substrate on an opposite side to the side, where the resonator is located, in the second part.

The high resistance region may be an insulating region provided on a surface of the substrate on an opposite side to a side, where the resonator is located, in the second part.

The present technique also provides a surface-emitting laser array including:
a first region in which a plurality of surface-emitting lasers are disposed in an array; and
a second region surrounding the first region,
wherein a first surface-emitting laser that is the surface-emitting laser outermost in the first region has a higher resistance than a second surface-emitting laser that is the surface-emitting laser further inward than the first surface-emitting laser in the first region.

The first surface-emitting laser may have a high-resistance region in which the first surface-emitting laser has a higher resistance than the second surface-emitting laser, and/or the second surface-emitting laser may have a low-resistance region in which the second surface-emitting laser has a lower resistance than the first surface-emitting laser.

When the first surface-emitting laser has the high-resistance region, the high-resistance region may be an insulating region or a semi insulating region, and when the second surface-emitting laser has the low resistance region, the low-resistance region may be an impurity region.

Each of the plurality of surface-emitting lasers may include a common substrate and a resonator disposed on the substrate; the second surface-emitting laser may have the low-resistance region; and the low resistance region may be provided in the resonator of the second surface-emitting laser.

The resonator may include a first structure disposed on the substrate and including a first reflector, an active layer disposed on the first structure, and a second structure disposed on the active layer and including a second reflector; and the low-resistance region may be an impurity region provided within the second structure of the second surface-emitting laser.

Each of the plurality of surface-emitting lasers may include a common substrate and a resonator disposed on the substrate; the resonator may include a first structure disposed on the substrate and including a first reflector, an active layer disposed on the first structure, and a second structure disposed on the active layer and including a second reflector; at least part of the resonator of two adjacent ones of the surface-emitting lasers may be continuous through a continuous part in a layering direction of the first structure; the second surface-emitting laser may have the low-resistance region; and the low resistance region may be provided at least in the continuous part between the resonators of the two adjacent ones of the second surface-emitting lasers.

Each of the plurality of surface-emitting lasers may include a common substrate and a resonator disposed on the substrate; the first surface-emitting laser may have the high-resistance region; and the high-resistance region may be provided in the resonator of the first surface-emitting laser.

The resonator may include a first structure disposed on the substrate and including a first reflector, an active layer disposed on the first structure, and a second structure disposed on the active layer and including a second reflector; and the high-resistance region may be an ion implantation region provided within the second structure of the first surface-emitting laser.

Each of the plurality of surface-emitting lasers may include a common substrate and a resonator disposed on the substrate; the resonator may include a first structure disposed on the substrate and including a first reflector, an active layer disposed on the first structure, and a second structure disposed on the active layer and including a second reflector; at least part of the resonator of two adjacent ones of the surface-emitting lasers may be continuous through a continuous part in a layering direction of the first structure; the second surface-emitting laser may have the high-resistance region; and the high-resistance region may be provided in a part of the first surface-emitting laser, in the continuous part between the resonators of adjacent ones of the first surface-emitting laser and the second surface-emitting laser.

### BRIEF DESCRIPTION OF DRAWINGS

FIG. 1 is a cross-sectional view of a surface-emitting laser array according to a first embodiment of the present technique.

FIG. 2 is a plan view of the surface-emitting laser array according to the first embodiment of the present technique.

FIG. 3 is a diagram illustrating a current density distribution within a cross-section of a conventional surface-emitting laser array.

FIG. 4 is a diagram illustrating an in-plane light emission intensity distribution of a surface-emitting laser array according to the present technique compared to an in-plane light emission intensity distribution of a conventional surface-emitting laser array.

FIG. 5 is a graph illustrating an amount of resistance increase required to make an in-plane light emission intensity distribution uniform in a surface-emitting laser array.

FIG. 6 is a flowchart illustrating an example of a method for manufacturing the surface-emitting laser array according to the first embodiment of the present technique.

FIGS. 7A to 7C are cross-sectional views illustrating respective steps in the example of the method for manufacturing the surface-emitting laser array according to the first embodiment of the present technique.

FIGS. 8A to 8C are cross-sectional views illustrating respective steps in the example of the method for manufacturing the surface-emitting laser array according to the first embodiment of the present technique.

FIGS. 9A and 9B are cross-sectional views illustrating respective steps in the example of the method for manufacturing the surface-emitting laser array according to the first embodiment of the present technique.

FIG. 10 is a cross-sectional view of a surface-emitting laser array according to a second embodiment of the present technique.

FIG. 11 is a flowchart illustrating an example of a method for manufacturing the surface-emitting laser array according to the second embodiment of the present technique.

FIGS. 12A and 12B are cross-sectional views illustrating respective steps in the example of the method for manufacturing the surface-emitting laser array according to the second embodiment of the present technique.

FIGS. 13A and 13B are cross-sectional views illustrating respective steps in the example of the method for manufacturing the surface-emitting laser array according to the second embodiment of the present technique.

FIG. 14 is a cross-sectional view of a surface-emitting laser array according to a third embodiment of the present technique.

FIG. 15 is a flowchart illustrating an example of a method for manufacturing the surface-emitting laser array according to the third embodiment of the present technique.

FIGS. 16A to 16C are cross-sectional views illustrating respective steps in the example of the method for manufacturing the surface-emitting laser array according to the third embodiment of the present technique.

FIGS. 17A and 17B are cross-sectional views illustrating respective steps in the example of the method for manufacturing the surface-emitting laser array according to the third embodiment of the present technique.

FIGS. 18A and 18B are cross-sectional views illustrating respective steps in the example of the method for manufacturing the surface-emitting laser array according to the third embodiment of the present technique.

FIG. 19 is a cross-sectional view of a surface-emitting laser array according to a fourth embodiment of the present technique.

FIG. 20 is a cross-sectional view of a surface-emitting laser array according to a fifth embodiment of the present technique.

FIG. 21 is a flowchart illustrating an example of a method for manufacturing the surface-emitting laser array according to the fifth embodiment of the present technique.

FIGS. 22A to 22C are cross-sectional views illustrating respective steps in the example of the method for manufacturing the surface-emitting laser array according to the fifth embodiment of the present technique.

FIGS. 23A to 23C are cross-sectional views illustrating respective steps in the example of the method for manufacturing the surface-emitting laser array according to the fifth embodiment of the present technique.

FIGS. 24A and 24B are cross-sectional views illustrating respective steps in the example of the method for manufacturing the surface-emitting laser array according to the fifth embodiment of the present technique.

FIG. 25 is a cross-sectional view of a surface-emitting laser array according to a sixth embodiment of the present technique.

FIG. 26 is a flowchart illustrating an example of a method for manufacturing the surface-emitting laser array according to the sixth embodiment of the present technique.

FIGS. 27A and 27B are cross-sectional views illustrating respective steps in the example of the method for manufacturing the surface-emitting laser array according to the sixth embodiment of the present technique.

FIGS. 28A and 28B are cross-sectional views illustrating respective steps in the example of the method for manufacturing the surface-emitting laser array according to the sixth embodiment of the present technique.

FIGS. 29A to 29C are cross-sectional views illustrating respective steps in the example of the method for manufacturing the surface-emitting laser array according to the sixth embodiment of the present technique.

FIG. 30 is a cross-sectional view of a surface-emitting laser array according to a seventh embodiment of the present technique.

FIG. 31 is a flowchart illustrating an example of a method for manufacturing the surface-emitting laser array according to the seventh embodiment of the present technique.

FIGS. 32A to 32C are cross-sectional views illustrating respective steps in the example of the method for manufacturing the surface-emitting laser array according to the seventh embodiment of the present technique.

FIGS. 33A to 33C are cross-sectional views illustrating respective steps in the example of the method for manufacturing the surface-emitting laser array according to the seventh embodiment of the present technique.

FIGS. 34A and 34B are cross-sectional views illustrating respective steps in the example of the method for manufacturing the surface-emitting laser array according to the seventh embodiment of the present technique.

FIG. 35 is a cross-sectional view of a surface-emitting laser array according to an eighth embodiment of the present technique.

FIG. 36 is a cross-sectional view of a surface-emitting laser array according to a ninth embodiment of the present technique.

FIG. 37 is a flowchart illustrating an example of a method for manufacturing the surface-emitting laser array according to the ninth embodiment of the present technique.

FIGS. 38A to 38C are cross-sectional views illustrating respective steps in the example of the method for manufacturing the surface-emitting laser array according to the ninth embodiment of the present technique.

FIGS. 39A to 39C are cross-sectional views illustrating respective steps in the example of the method for manufacturing the surface-emitting laser array according to the ninth embodiment of the present technique.

FIGS. 40A and 40B are cross-sectional views illustrating respective steps in the example of the method for manufacturing the surface-emitting laser array according to the ninth embodiment of the present technique.

FIG. 41 is a cross-sectional view of a surface-emitting laser array according to a tenth embodiment of the present technique.

FIG. 42 is a flowchart illustrating an example of a method for manufacturing the surface-emitting laser array according to the tenth embodiment of the present technique.

FIGS. 43A and 43B are cross-sectional views illustrating respective steps in the example of the method for manufacturing the surface-emitting laser array according to the tenth embodiment of the present technique.

FIGS. 44A to 44C are cross-sectional views illustrating respective steps in the example of the method for manufacturing the surface-emitting laser array according to the tenth embodiment of the present technique.

FIGS. 45A to 45D are cross-sectional views of surface-emitting laser arrays according to first to fourth variations, respectively, on the first embodiment of the present technique.

FIGS. 46A to 46C are cross-sectional views of surface-emitting laser arrays according to first to third variations, respectively, on the second embodiment of the present technique.

FIGS. 47A to 47C are cross-sectional views of surface-emitting laser arrays according to first to third variations, respectively, common to the first and second embodiments of the present technique.

FIGS. 48A to 48D are cross-sectional views of surface-emitting laser arrays according to fourth to seventh variations, respectively, common to the first and second embodiments of the present technique.

FIGS. 49A and 49B are cross-sectional views of surface-emitting laser arrays according to eighth and ninth variations, respectively, common to the first and second embodiments of the present technique.

FIGS. 50A to 50C are cross-sectional views of surface-emitting laser arrays according to first to third variations, respectively, on the third embodiment of the present technique.

FIGS. 51A to 51D are cross-sectional views of surface-emitting laser arrays according to first to fourth variations, respectively, on the sixth embodiment of the present technique.

FIGS. 52A to 52D are cross-sectional views of surface-emitting laser arrays according to fifth to eighth variations, respectively, on the sixth embodiment of the present technique.

FIG. 53A is a cross-sectional view of a surface-emitting laser array according to a first variation on the fourth embodiment of the present technique. FIG. 53B is a cross-sectional view of a surface-emitting laser array according to a first variation on the fifth embodiment of the present technique. FIG. 53C is a cross-sectional view of a surface-emitting laser array according to a variation common to the fourth and fifth embodiments of the present technique.

FIG. 54A is a cross-sectional view of a surface-emitting laser array according to a first variation on the seventh embodiment of the present technique. FIG. 54B is a cross-sectional view of a surface-emitting laser array according to a second variation on the seventh embodiment of the present technique.

FIG. 55A is a cross-sectional view of a surface-emitting laser array according to a third variation on the seventh embodiment of the present technique. FIG. 55B is a cross-sectional view of a surface-emitting laser array according to a fourth variation on the seventh embodiment of the present technique.

FIG. 56A is a cross-sectional view of a surface-emitting laser array according to a first variation on the eighth embodiment of the present technique. FIG. 56B is a cross-sectional view of a surface-emitting laser array according to a second variation on the eighth embodiment of the present technique.

FIG. 57A is a cross-sectional view of a surface-emitting laser array according to a third variation on the eighth embodiment of the present technique. FIG. 57B is a cross-sectional view of a surface-emitting laser array according to a fourth variation on the eighth embodiment of the present technique.

FIGS. 58A to 58C are cross-sectional views of surface-emitting laser arrays according to first to third variations, respectively, common to the ninth and tenth embodiments of the present technique.

FIG. 59 is a diagram illustrating an example of the application of the surface-emitting laser array according to the first embodiment of the present technique to a distance measurement device.

FIG. 60 is a block diagram illustrating an example of the schematic configuration of a vehicle control system.

FIG. 61 is an explanatory diagram illustrating an example of installation positions of distance measurement devices.

### DESCRIPTION OF EMBODIMENTS

Hereinafter, preferred embodiments of the present technique will be described in detail with reference to the accompanying drawings. Note that in the present specification and the drawings, components having substantially the same functional configurations will be denoted by the same reference numerals, and descriptions thereof will not be repeated. The following embodiments describe representative embodiments of the present technique, and the scope of the present technique should not be narrowly interpreted on the basis thereof. Even if the surface-emitting laser array according to the present technique is described herein as exhibiting a plurality of advantageous effects, the surface-emitting laser array according to the present technique need only exhibit at least one advantageous effect. The advantageous effects described herein are merely exemplary and are not limited, and other advantageous effects may be achieved.

### The Descriptions Will Be Given in the Following Order.

0. Introduction
1. Surface-Emitting Laser Array According to First Embodiment of Present Technique
2. Surface-Emitting Laser Array According to Second Embodiment of Present Technique
3. Surface-Emitting Laser Array According to Third Embodiment of Present Technique
4. Surface-Emitting Laser Array According to Fourth Embodiment of Present Technique
5. Surface-Emitting Laser Array According to Fifth Embodiment of Present Technique
6. Surface-Emitting Laser Array According to Sixth Embodiment of Present Technique
7. Surface-Emitting Laser Array According to Seventh Embodiment of Present Technique
8. Surface-Emitting Laser Array According to Eighth Embodiment of Present Technique
9. Surface-Emitting Laser Array According to Ninth Embodiment of Present Technique
10. Surface-Emitting Laser Array According to Tenth Embodiment of Present Technique
11. Variations on Present Technique
12. Example of Application to Electronic Device
13. Example of Applying Surface-Emitting Laser Array to Distance Measurement Device
14. Example of Installing Distance Measurement Device on Moving Body

### 0. Introduction

One of the challenges of surface-emitting laser arrays (VCSEL arrays) currently used in sensing and optical communication applications is to suppress variations in in-plane light emission intensity from the standpoint of mode control, reliability, and the like. As one cause of variation in the light emission intensity, it has been reported that surface-emitting lasers located further inward in the surface-emitting laser array than the surface-emitting laser on the outermost side have a wider effective current path, which increases the current injection amount and increases the optical output.

In other words, in conventional surface-emitting laser arrays, the light emission intensity of the outermost surface-emitting laser of the surface-emitting laser array is higher than that of surface-emitting lasers further inward therefrom, and the in-plane light emission intensity distribution of the surface-emitting laser array therefore becomes imbalanced.

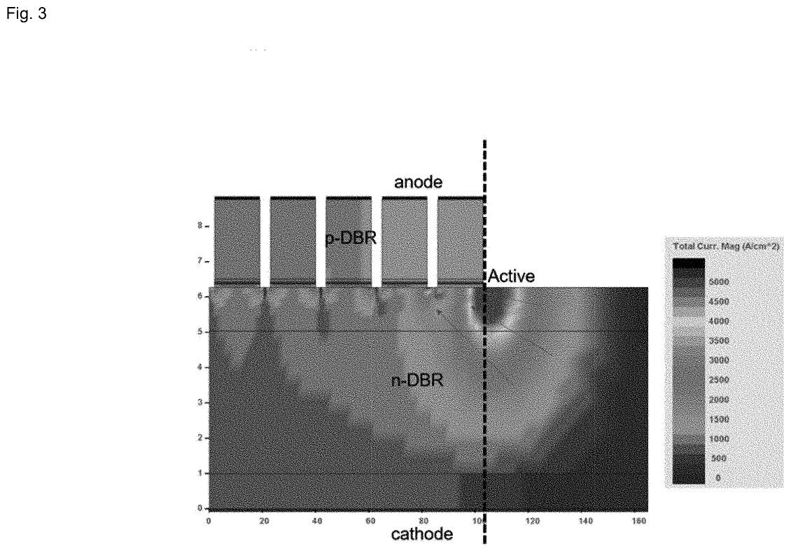

FIG. 3 is a diagram illustrating a result of measuring a current density distribution near the outer peripheral part of a conventional surface-emitting laser array. In the surface-emitting laser array in FIG. 3, an anode electrode is disposed at the top of the mesa of each surface-emitting laser, and a cathode electrode is disposed on the rear surface of the substrate. In FIG. 3, regions having higher current density are indicated by darker colors, and it can be seen that there is a region having an extremely high current density immediately below the mesa of the outermost surface-emitting laser of the surface-emitting laser array. This is because the current supplied from the cathode electrodes around the region where the surface-emitting laser array is disposed concentrates in the mesa of the outermost surface-emitting laser.

In the surface-emitting laser array described in PTL 1, the density of the mesas in the outer peripheral part is made sparser than in the inner peripheral part. This suppresses current consumption in areas close to the outer peripheral part and ensures that a sufficient amount of current is supplied to a center part, which in turn suppresses a decrease in the light emission intensity in the center part. In-plane variation in the light emission intensity can be suppressed as a result. However, in PTL 1, it is necessary to increase the mesa interval with proximity to the outer side, which risks increasing the scale of the array.

The surface-emitting laser array described in PTL 2 has a layered electrode structure including first and second upper electrodes in which outer peripheral parts thereof are layered with an insulating film therebetween, and inner peripheral parts are layered directly on each other. The boundary between the outer peripheral part and the inner peripheral part of each of first and second upper electrodes is located near the central part of the array, and the voltage near the central part can be made relatively small. In-plane variation in the light emission intensity can be suppressed as a result. However, since an opening serving as an outlet is defined by the layered electrode structure described above, there is a risk that vignetting will occur.

Accordingly, after diligent investigations, the inventors developed the surface-emitting laser array according to the present technique as a surface-emitting laser array capable of suppressing in-plane variation in light emission intensity while suppressing an increase in the scale of the array and the occurrence of vignetting.

Several embodiments of the surface-emitting laser array according to the present technique will be described in detail hereinafter with reference to the drawings. In each cross-sectional view, the upper side will be described as the “top” and the lower side as the “bottom” when appropriate.

### 1. Surface-Emitting Laser Array According to First Embodiment of Present Technique

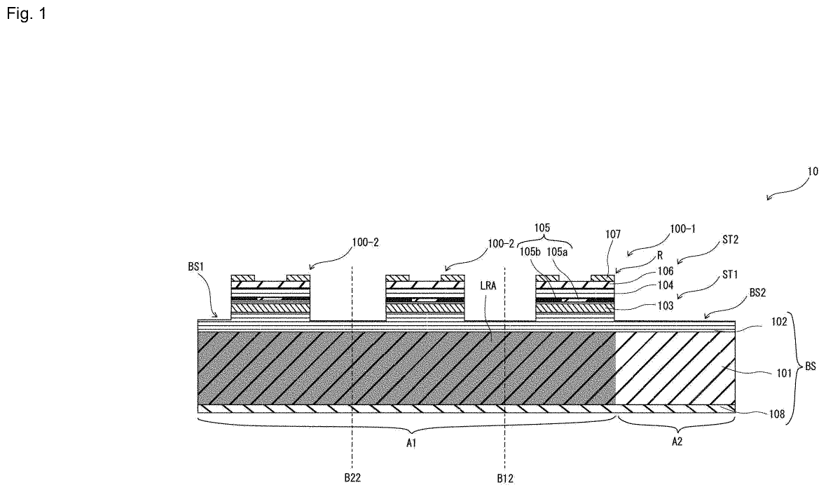

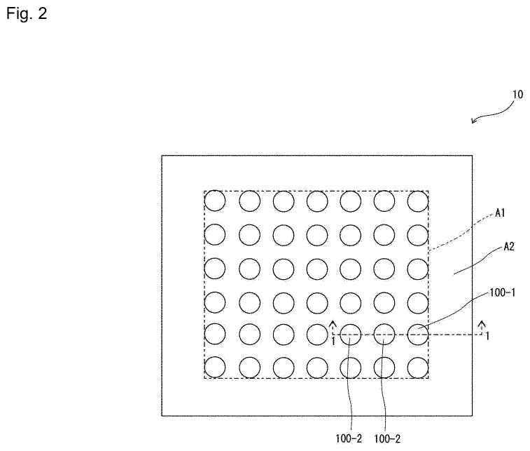

FIG. 1 is a cross-sectional view of a surface-emitting laser array 10 according to a first embodiment of the present technique. FIG. 2 is a plan view of the surface-emitting laser array 10 according to the first embodiment of the present technique. FIG. 1 is a cross-sectional view taken along line 1-1 in FIG. 2.

### Configuration of Surface-Emitting Laser Array

Overall Configuration The surface-emitting laser array 10 according to the first embodiment of the present technique is, for example, a front surface-emitting type of surface-emitting laser array. In one example, as illustrated in FIGS. 1 and 2, the surface-emitting laser array 10 includes a first region A1 in which a plurality of (e.g., 42) surface-emitting lasers 100 (e.g., surface-emitting lasers 100-1 and 100-2) are arranged in an array, and a second region A2 in the periphery of the first region A1. Each surface-emitting laser 100 is a vertical cavity surface emitting laser (VCSEL). Each surface-emitting laser 100 is driven by a laser driver, for example.

In the surface-emitting laser array 10, the planar arrangement of the plurality of surface-emitting lasers 100 is, for example, a matrix (e.g., a 6×7 matrix) (see FIG. 2). The planar arrangement of the plurality of surface-emitting lasers 100 may, however, be another two-dimensional arrangement, such as a staggered arrangement. Here, in plan view, the first region A1, which is rectangular, is surrounded by the second region A2, which has a rectangular frame shape. The plan view shapes of the first and second regions A1 and A2 can be changed as appropriate. The surface-emitting laser array 10 is not limited to a two-dimensional array, and may be a one-dimensional array, but in either case, it is preferable that three or more surface-emitting lasers 100 be included.

Of first and second parts BS1 and BS2, which are adjacent in the in-plane direction of a base structure BS including a substrate 101, the first part BS1 (e.g., a part that is rectangular in plan view) is included in the first region A1. The second part BS2 of the base structure BS (e.g., the part having a rectangular frame shape in plan view) is included in the second region A2. In one example, the second part BS is constituted by the second region A2.

Here, in the base structure BS, the first part BS1 is surrounded by the second part BS2. In one example, in plan view, an outer edge of the first part BS1 coincides with an outer edge of the first region A1. In one example, the base structure BS further includes a cathode electrode 108 (an n-side electrode) provided in a continuous shape on the rear surface (bottom surface) of the substrate 101, and a part (bottom part) of a first reflector 102 provided on the substrate 101.

Each of the plurality of surface-emitting lasers 100 has a common substrate 101 and a resonator R disposed on the substrate 101. The resonator R includes a first structure ST1 including the first reflector 102 and disposed on the substrate 101, an active layer 103 disposed on the first structure ST1, and a second structure ST2 including a second reflector 104 and disposed on the active layer 103. The second structure ST2 further includes an oxide confinement layer 105 disposed within the second reflector 104 and a contact layer 106 disposed on the second reflector 104. Here, the first structure ST1 is constituted by the first reflector 102. The first structure ST1 shares a part (the bottom part of the first reflector 102) with the base structure BS. In other words, at least a part of the first structure ST1 with respect to the layering direction (e.g., the bottom part of the first reflector 102) is also disposed on the substrate 101 around the periphery of each resonator R of the plurality of surface-emitting lasers 100.

The resonator R of each surface-emitting laser 100 has a mesa configured including a part (a top part) of the first structure ST1, the active layer 103, and the second structure ST2. In other words, the mesa is formed in a projecting form on the top surface of the base structure BS. In one example, each mesa has approximately the same height (e.g., approximately 4 to 6 μm). Although the shape of each mesa in plan view is assumed to be circular here (see FIG. 2), other shapes may be used, such as an ellipse, a polygon, or the like, for example. Each mesa is also called a “light-emitting mesa”.

For example, a ring-shaped anode electrode 107 (a p-side electrode) is provided on the top of the mesa of each resonator R (e.g., the contact layer 106). The inner diameter side of the anode electrode 107 serves as an outlet.

In other words, in the surface-emitting laser array 10, a separate anode electrode 107 is provided on each surface-emitting laser 100, whereas the cathode electrode 108 is provided in common for the surface-emitting lasers 100. The surface-emitting laser array 10 is mounted junction-up on a laser driver, for example. Each anode electrode 107 is electrically connected to the anode of the laser driver, for example. The cathode electrode 108 is electrically connected to the cathode of the laser driver. Each surface-emitting laser 100 can also be independently driven by the laser driver.

### Substrate

The substrate 101 is formed from, for example, a semiconductor substrate (e.g., a GaAs substrate) of a first conductivity type (e.g., n type).

### Cathode Electrode

Au/Ni/AuGe, Au/Pt/Ti, or the like can be given as examples of the material of the cathode electrode 108.

### First Reflector

In one example, the first reflector 102 is a semiconductor multilayer reflector. The multilayer reflector is also called a Distributed Bragg Reflector (DBR). Specifically, the first reflector 102 is, for example, a semiconductor multilayer reflector of the first conductivity type (e.g., n type), and has a structure in which a plurality of types (e.g., two types) of semiconductor layers having different refractive indices from each other are alternately layered at an optical thickness of ¼ of the oscillation wavelength. In one example, each refractive index layer of the first reflector 102 is formed from an AlGaAs-based compound semiconductor of the first conductivity type (e.g., n type). The first reflector 102 is also called a lower reflector.

### Active Layer

The active layer 103 has a quantum well structure including, for example, a barrier layer constituted by a GaAs-based compound semiconductor (e.g., InGaAs), and a quantum well layer. The quantum well structure may be a single quantum well structure (QW structure) or a multiple quantum well structure (MQW structure).

In one example, in the active layer 103, the region corresponding to a non-oxide region 105a of the oxide confinement layer 105 is a light-emitting region. The active layer 103 may have a plurality of QW structures or a plurality of MQW structures layered with tunnel junctions therebetween.

### Second Reflector

The second reflector 104 is, for example, a semiconductor multilayer reflector. Specifically, the second reflector 104 is, for example, a semiconductor multilayer reflector of a second conductivity type (e.g., p type), and has a structure in which a plurality of types (e.g., two types) of semiconductor layers having different refractive indices from each other are alternately layered at an optical thickness of ¼ of the oscillation wavelength. In one example, each refractive index layer of the second reflector 104 is formed from an AlGaAs-based compound semiconductor of the second conductivity type (e.g., p type). The second reflector 104 is set to have a slightly lower reflectance than the first reflector 102. The second reflector 104 is also called an upper reflector.

### Oxide Confinement Layer

The oxide confinement layer 105 has a current confinement function and a light confinement function. The oxide confinement layer 105 has the non-oxide region 105a and an oxide region 105b surrounding the non-oxide region 105a. The non-oxide region 105a is constituted by, for example, AlGaAs or AlAs, and the oxide region 105b includes an insulator, e.g., AlₓO_{y}. The oxide region 105b has a higher electrical resistance and a lower refractive index than the non-oxide region 105a, and functions as a current confinement region and a light confinement region. The non-oxide region 105a functions as a current passage region. The diameter of the light-emitting region (the current injection diameter of the current injection region) is set by the oxide confinement diameter (the inner diameter of the oxide region 105b).

### Contact Layer

In one example, the contact layer 106 is formed from a GaAs layer of the second conductivity type (e.g., p type). The contact layer 106 has a higher doping concentration and carrier conductivity than the second reflector 104.

### (Anode Electrode)

Au/Ni/AuGe, Au/Pt/Ti, or the like can be given as examples of the material of the anode electrode 107.

### Average Resistance

In the base structure BS, the average resistance (average value of electrical resistance) of the second part BS2 is higher than that of the first part BS1. In other words, in the base structure BS, the first part BS1 has a lower average resistance than the second part BS2. To be more specific, the first part BS1 has a low-resistance region LRA (the gray region in FIG. 1) in which the average resistance of the first part BS1 is lower than the average resistance of the second part BS2.

In one example, the low-resistance region LRA is an impurity region. The low-resistance region LRA is a region doped with n-type impurities, for example. Si, Se, Te, and the like can be given as examples of the n-type impurity (dopant). The doping concentration (impurity concentration) of the low-resistance region LRAis set to be higher than the doping concentration of the n-type impurities in the substrate 101 in the second part BS2 (the second region A2), for example. The doping concentration of the low-resistance region LRA may be uniform across the entire region, or may be non uniform (e.g., may have a distribution, such as a gradation, steps, or the like). Suitable values for the impurity concentration in the low-resistance region LRA will be described later.

In one example, the low-resistance region LRA is provided within the substrate 101. In one example, the low-resistance region LRA is provided throughout the entirety of the substrate 101 in the first part BS1.

Hereinafter, in the surface-emitting laser array 10, an outermost surface-emitting laser 100 will also be called a first surface-emitting laser 100-1, and a surface-emitting laser further inward than the surface-emitting laser 100-1 will also be called a second surface-emitting laser 100-2.

In one example, as illustrated in FIG. 1, in the surface-emitting laser array 10, a boundary line between adjacent ones of the first and second surface-emitting lasers 100-1 and 100-2 can be set as B12, and a boundary line between two adjacent second surface-emitting lasers 100-2 and 100-2 can be set as B22.

In the low-resistance region LRA, a rectangular line (the double dot-dash line in FIG. 2) inscribed by the mesas of the plurality of first surface-emitting lasers 100-1 serves as an outer edge.

Due to the low-resistance region LRA, the average resistance of the substrate 101 in the first part BS1 is lower than the average resistance of the substrate 101 in the second part BS2, which makes it easy for current to flow to the second surface-emitting laser 100-2. As a result, in-plane variation in the light emission intensity can be suppressed in the surface-emitting laser array 10.

### Amount of Change in Average Resistance for Suppressing In-Plane Variation in Light Emission Intensity

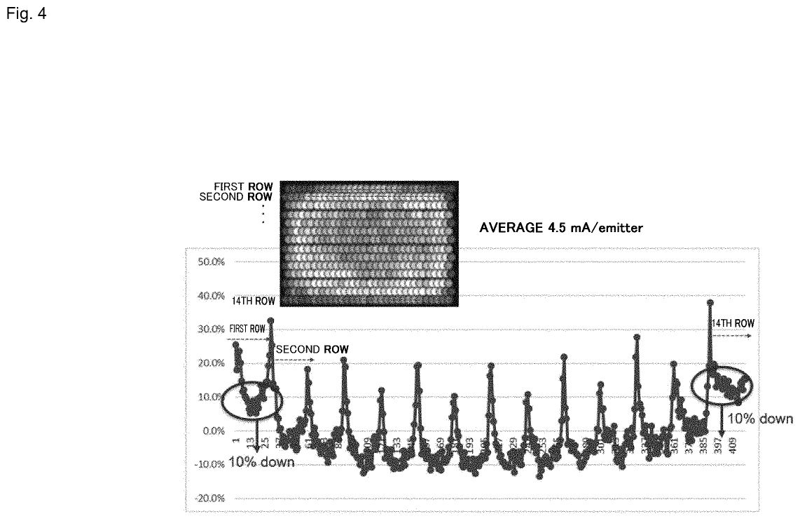

The degree to which the average resistance of the first part BS1 is to be lower than the average resistance of the second part BS2 in the base structure BS (an average resistance reduction amount) to suppress in-plane variation in the light emission intensity will be described next. FIG. 4 is a diagram illustrating an in-plane light emission intensity distribution of the surface-emitting laser array according to the present technique compared to an in plane light emission intensity distribution of a conventional surface-emitting laser array. In FIG. 4, the light emission amounts of the light-emitting mesas, standardized for each row of the surface-emitting laser array, are listed for all rows (rows 1 to 14). It can be seen that the light emission intensity is 10% higher in the outermost light-emitting mesas (rows 1 and 14) than in the light-emitting mesas in the other rows. Accordingly, it is preferable to calculate an average resistance increase amount, which is an amount of increase in the average resistance of the second part BS2 relative to the average resistance of the first part BS1, in order to reduce the light emission intensity by 10% for the outermost light-emitting mesas. A suitable value for the impurity concentration in the low-resistance region LRA for sufficiently suppressing in plane variation in the light emission intensity can be determined on the basis of the result of calculating the average resistance increase amount.

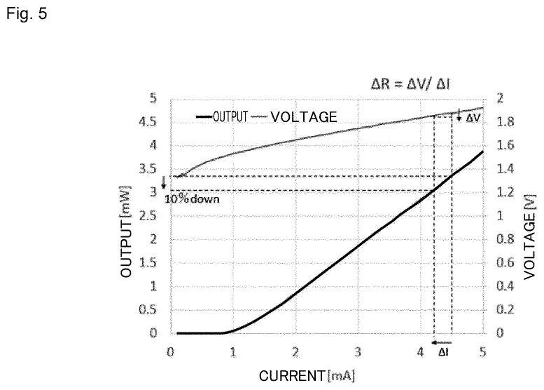

FIG. 5 is a graph illustrating the average resistance increase amount required to sufficiently suppress in plane variation in the light emission intensity in the surface-emitting laser array. The output/current characteristics and the voltage/current characteristics per single light-emitting mesa in FIG. 4 are shown in FIG. 5. A quotient of a current reduction amount AI and a voltage reduction amount ΔV when the output (light emission intensity) decreases by 10% (ΔV/ΔI) is an average resistance increase amount ΔR to be obtained. The result of calculating the average resistance increase amount ΔR is ΔR=0.083 [Ω]. In-plane variation in the light emission intensity can be sufficiently suppressed if this average resistance increase amount can be achieved in the outermost light-emitting mesa. To put this conversely, in plane variation in the light emission intensity can be sufficiently suppressed if the average resistance reduction amount AR can be achieved more in the inner light-emitting mesas than in the outermost light-emitting mesa.

The foregoing describes calculating the average resistance change amount (the average resistance increase amount or the average resistance decrease amount) for reducing the light emission intensity by about 10% (for sufficiently suppressing in-plane variation in the light emission intensity), and then determining a suitable value for the impurity concentration in the low-resistance region LRA on the basis of the result of the calculation. However, the configuration is not limited thereto. An average resistance increase amount for reducing the light emission intensity by less than 10%, e.g., 8%, 5%, or 3%, may be calculated, and a suitable value for the impurity concentration in the low-resistance region LRA may then be determined on the basis of the average resistance increase amount. Even in this case, in-plane variation in the light emission intensity can be suppressed to some extent.

### Operation of Surface-Emitting Laser Array

The operation of the surface-emitting laser array 10 will be described hereinafter with reference to FIG. 1. When a driving voltage of the laser driver is applied to the first and second surface-emitting lasers 100-1 and 100-2 of the surface-emitting laser array 10, current from the anode side of the laser driver is injected into the light-emitting region of the active layer 103 through the second reflector 104 in which the anode electrode 107, the contact layer 106, and the oxide confinement layer 105 of the surface-emitting laser 100 are provided, in that order. At this time, when the light-emitting region of each surface-emitting laser 100 emits light, the light travels back and forth between the first and second reflectors 102 and 104 while being amplified by the active layer 103 and confined by the oxide confinement layer 105, and an oscillation condition is met, the light is emitted as a laser beam from the outlet on the inner diameter side of the anode electrode 107. At this time, the difference in the magnitudes of the currents flowing in the first and second surface-emitting lasers 100-1 and 100-2 is small due to the effect of the low-resistance region LRA, and thus the difference in the light emission intensity of the first and second surface-emitting lasers 100-1 and 100-2 is also small, which suppresses in plane variation in the light emission intensity. The current flowing through the active layer 103 flows out to the cathode side of the laser driver via the first reflector 102, the substrate 101, and the cathode electrode 108, in that order.

### Manufacturing Method for Surface-Emitting Laser Array

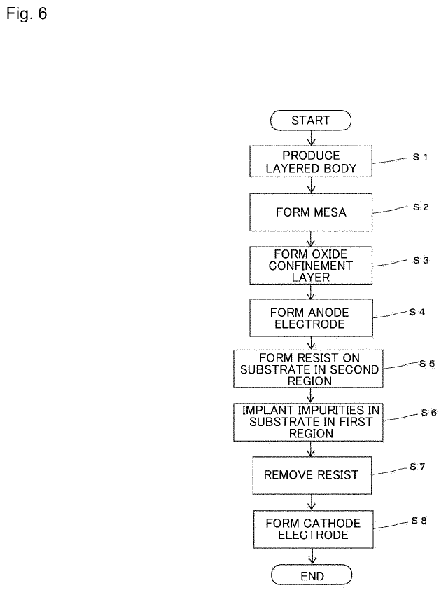

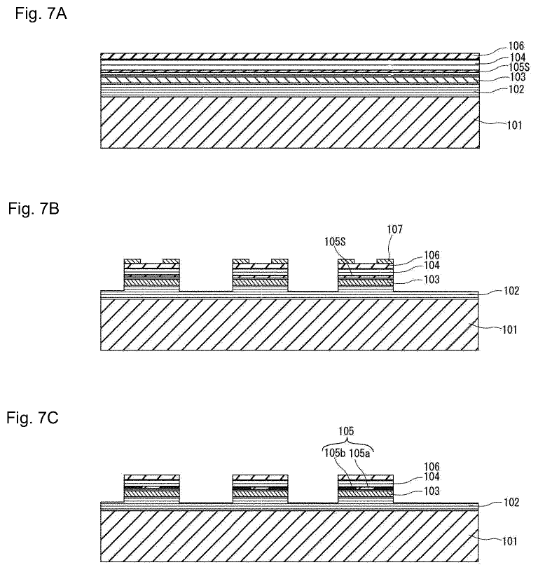

A method for manufacturing the surface-emitting laser array 10 will be described hereinafter with reference to the flowchart in FIG. 6 and the like. FIGS. 7A to 9B are cross-sectional process views corresponding to the cross-section along line 1-1 in FIG. 2. As the overall flow, first, a plurality of surface-emitting laser arrays 10 are produced simultaneously on a single wafer serving as the substrate 101 (called simply the “substrate 101” for convenience hereinafter) through a semiconductor manufacturing method using a semiconductor manufacturing device. Next, the series of the plurality of integrated surface-emitting laser arrays 10 are separated from each other through dicing to obtain a chip-shaped surface-emitting laser array 10. In the following descriptions, for convenience, the region corresponding to the first region A1 will be called the “first region A1”, and the region corresponding to the second region A2 will be called the “second region A2”.

In the first step, step S1, a layered body is produced (see FIG. 7A). Specifically, a layered body is produced by layering the first reflector 102, the active layer 103, the second reflector 104 having an oxidized layer 105S (e.g., an AlAs layer or an AlGaAs layer) serving as the material of the oxide confinement layer 105, and the contact layer 106 in that order on the substrate 101 (e.g., an n-GaAs substrate) serving as a growth substrate, through an epitaxial crystal growth method such as Metal Organic Chemical Vapor Deposition (MOCVD), for example. At this time, a methyl-based organic metal gas such as trimethyl aluminum (TMAI), trimethyl gallium (TMGa), trimethyl indium (TMIn), or the like, and arsine (AsH₃) gas, are used as the materials for the compound semiconductor, for example; disilane (Si₂H₆) is used as the material for donor impurities, for example; and carbon tetrachloride (CBr₄) is used as the material for acceptor impurities, for example.

In the next step, step S2, a mesa is formed (see FIG. 7B). Specifically, using photolithography, a resist is formed covering the location where the mesa of each surface-emitting laser 100 is to be formed on the layered body, and the layered body is etched through dry etching or wet etching using the resist as a mask. The etching at this time is performed to a depth that ensures the etching bottom surface is located within the first reflector 102, for example. A mesa in which the side surfaces of the oxidized layer 105S are exposed is formed as a result. The resist is then removed.

In the next step, step S3, an oxide confinement layer is formed (see FIG. 7C). Specifically, each mesa is exposed to a high-temperature water vapor atmosphere, and the oxidized layer 105S is oxidized from the side surfaces to form the oxide confinement layer 105 in which the non-oxide region 105a is surrounded by the oxide region 105b.

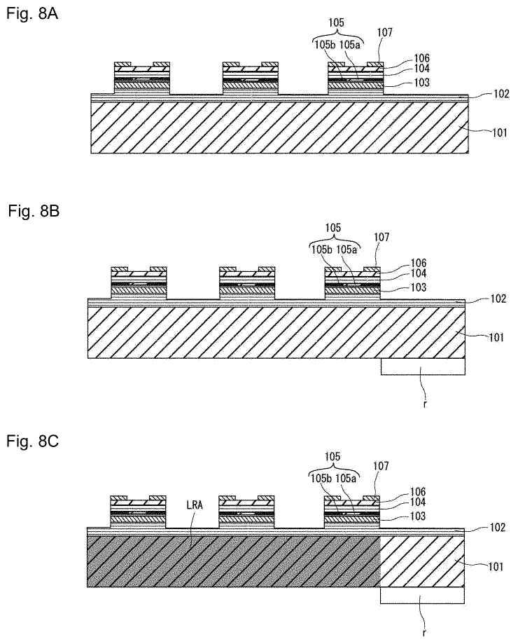

In the next step, step S4, the anode electrode 107 is formed (see FIG. 8A). Specifically, the ring-shaped anode electrode 107 is formed at the top of each mesa through a lift-off method, for example. At this time, vapor deposition, sputtering, or the like is used for the deposition of the electrode material, for example.

In the next step, step S5, a resist r is formed on the rear surface of the substrate 101 in the second region A2 (see FIG. 8B). Specifically, through photolithography, a rectangular frame-shaped resist r is formed on the rear surface (the bottom surface) of the substrate 101 in the second region A2.

In the next step, step S6, impurities are implanted in the substrate 101 in the first region A1 (see FIG. 8C). Specifically, using the resist r as a mask, impurities (e.g., n-type impurities) are implanted from the rear surface side of the substrate 101 in the first region A1 over the entirety of the substrate 101, to a predetermined impurity concentration (e.g., an impurity concentration corresponding to the foregoing AR) that is higher than the impurity concentration of the substrate 101 in the second region A2.

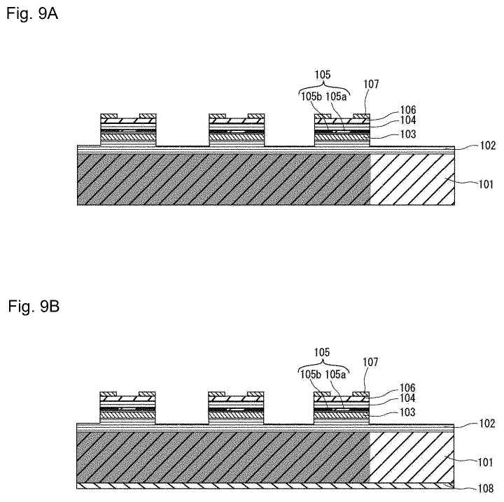

In the next step, step S7, the resist r is removed (see FIG. 9A). Specifically, the resist r is removed by wet etching or the like, for example.

In the final step, step S8, the cathode electrode 108 is formed (see FIG. 9B). Specifically, the cathode electrode 108 is formed in a solid shape on the rear surface of the substrate 101 through a lift-off method, for example. At this time, vapor deposition, sputtering, or the like is used for the deposition of the electrode material, for example.

### Effects of Surface-Emitting Laser Array

The surface-emitting laser array 10 according to the first embodiment of the present technique includes the first region A1 in which a plurality of the surface-emitting lasers 100 are disposed in an array, and the second region A2 surrounding the first region A1. Among the first and second parts BS1 and BS2, which are adjacent in an plane direction, of the base structure BS including the substrate 101,, the first part BS1 is included in the first region A1 and the second part BS2 is included in the second region A2. The average resistance of the first part BS1 is lower than the average resistance of the second part BS2.

In the surface-emitting laser array 10, the average resistance of the first part BS1 is lower than the average resistance of the second part BS2, and current therefore flows more easily in the outermost surface-emitting laser 100 of the surface-emitting laser array 10 than in surface-emitting lasers 100 further inward than the outermost surface-emitting laser 100. As a result, in-plane variation in the light emission intensity can be suppressed. In addition, in the surface-emitting laser array 10, it is not necessary to make the outer peripheral part of the array sparser than the inner peripheral part, which makes it possible to suppress an increase in size. Furthermore, it is not necessary to form the anode electrode 107 that defines the outlet in a thick form, which makes it possible to suppress vignetting.

As a result, according to the surface-emitting laser array 10, a surface-emitting laser array can be provided which is capable of suppressing in plane variation in light emission intensity while suppressing an increase in the scale of the array and the occurrence of vignetting.

### 2. Surface-Emitting Laser Array According to Second Embodiment of Present Technique

### Configuration of Surface-Emitting Laser Array

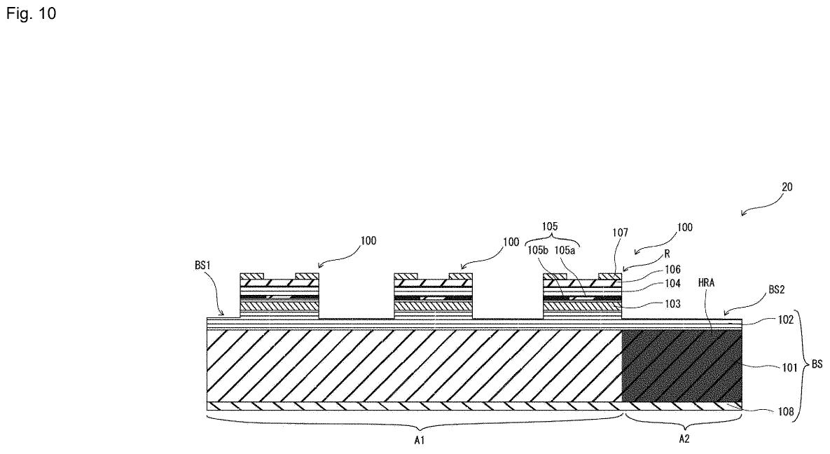

FIG. 10 is a cross-sectional view of a surface-emitting laser array 20 according to a second embodiment of the present technique. As illustrated in FIG. 10, the surface-emitting laser array 20 has the same configuration as the surface-emitting laser array 10 according to the first embodiment, except that the first part BS1 of the base structure BS does not have the low-resistance region LRA, and the second part BS2 has a high-resistance region HRA (the dark gray region in FIG. 10) in which the average resistance of the second part BS2 is higher than the average resistance of the first part BS1.

In one example, the high-resistance region HRA is an insulating region or a semi-insulating region. Specifically, the high-resistance region HRA is, in one example, an ion implantation region. In one example, the ion implantation region serving as the high-resistance region HRA is provided throughout the entirety of the substrate 101 in the second part BS2. For example, H+, B+, and the like can be given as examples of the ion species in the ion implantation region. The ion concentration of the ion implantation region may be uniform across the entire region, or may be non-uniform (e.g., may have a distribution, such as a gradation, steps, or the like). For example, a suitable value for the ion concentration of the ion implantation region can be calculated on the basis of the foregoing AR.

### Manufacturing Method for Surface-Emitting Laser Array

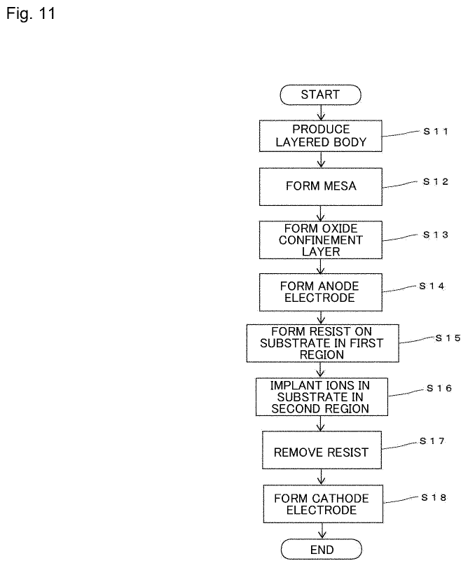

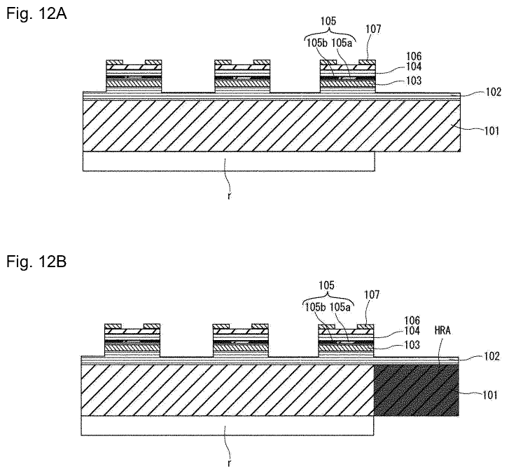

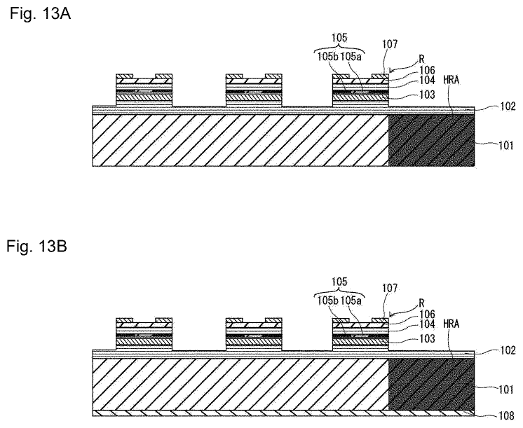

A method for manufacturing the surface-emitting laser array 10 will be described hereinafter with reference to the flowchart in FIG. 11 and the like. FIGS. 12A to 13B are cross-sectional process views corresponding to the cross-section along line 1-1 in FIG. 2. As the overall flow, first, a plurality of surface-emitting laser arrays 20 are produced simultaneously on a single wafer serving as the substrate 101 (called simply the “substrate 101” for convenience hereinafter) through a semiconductor manufacturing method using a semiconductor manufacturing device. Next, the series of the plurality of integrated surface-emitting laser arrays 20 are separated from each other through dicing to obtain a chip-shaped surface-emitting laser array 20. In the following descriptions, for convenience, the region corresponding to the first region A1 will be called the “first region A1”, and the region corresponding to the second region A2 will be called the “second region A2”.

In the first step, step S11, a layered body is produced (see FIG. 7A). Specifically, a layered body is produced by layering the first reflector 102, the active layer 103, the second reflector 104 having an oxidized layer 105S (e.g., an AlAs layer or an AlGaAs layer) serving as the material of the oxide confinement layer 105, and the contact layer 106 in that order on the substrate 101 (e.g., an n-GaAs substrate) serving as a growth substrate, through an epitaxial crystal growth method such as Metal Organic Chemical Vapor Deposition (MOCVD), for example. At this time, a methyl-based organic metal gas such as trimethyl aluminum (TMAI), trimethyl gallium (TMGa), trimethyl indium (TMIn), or the like, and arsine (AsH₃) gas, are used as the materials for the compound semiconductor, for example; disilane (Si₂H₆) is used as the material for donor impurities, for example; and carbon tetrachloride (CBr₄) is used as the material for acceptor impurities, for example.

In the next step, step S12, a mesa is formed (see FIG. 7B). Specifically, using photolithography, a resist is formed covering the location where the mesa of each surface-emitting laser 100 is to be formed on the layered body, and the layered body is etched through dry etching or wet etching using the resist as a mask. The etching at this time is performed to a depth that ensures the etching bottom surface is located within the first reflector 102, for example. A mesa in which the side surfaces of the oxidized layer 105S are exposed is formed as a result. The resist is then removed.

In the next step, step S13, an oxide confinement layer is formed (see FIG. 7C). Specifically, each mesa is exposed to a high temperature water vapor atmosphere, and the oxidized layer 105S is oxidized from the side surfaces to form the oxide confinement layer 105 in which the non-oxide region 105a is surrounded by the oxide region 105b.

In the next step, step S14, the anode electrode 107 is formed (see FIG. 8A). Specifically, the ring-shaped anode electrode 107 is formed at the top of each mesa through a lift-off method, for example. At this time, vapor deposition, sputtering, or the like is used for the deposition of the electrode material, for example.

In the next step, step S15, a resist r is formed on the rear surface of the substrate 101 in the first region A1 (see FIG. 12A). Specifically, through photolithography, a rectangular resist r is formed on the rear surface (the bottom surface) of the substrate 101 in the first region A1.

In the next step, step S16, ion implantation is performed on the substrate 101 in the second region A1 (see FIG. 12B). Specifically, using the resist r as a mask, ions are implanted from the rear surface side of the substrate 101 in the second region A2 to a predetermined concentration (e.g., a concentration corresponding to the foregoing AR) over the entirety of the substrate 101.

In the next step, step S17, the resist r is removed (see FIG. 13A). Specifically, the resist r is removed by wet etching or the like, for example.

In the final step, step S18, the cathode electrode 108 is formed (see FIG. 13B). Specifically, the cathode electrode 108 is formed in a solid shape on the rear surface of the substrate 101 through a lift-off method, for example. At this time, vapor deposition, sputtering, or the like is used for the deposition of the electrode material, for example.

### Effects of Surface-Emitting Laser Array

According to the surface-emitting laser array 20 of the second embodiment, the same effects as the surface-emitting laser array 10 according to the first embodiment can be achieved.

### 3. Surface-Emitting Laser Array According to Third Embodiment of Present Technique

### Configuration of Surface-Emitting Laser Array

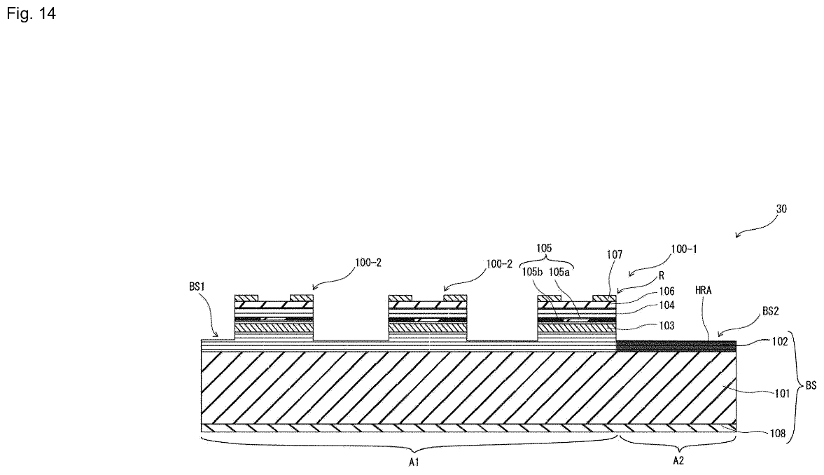

FIG. 14 is a cross-sectional view of a surface-emitting laser array 30 according to a third embodiment of the present technique. As illustrated in FIG. 14, the surface-emitting laser array 30 has the same configuration as the surface-emitting laser array 20 according to the second embodiment, except that the second part BS2 has the high resistance region HRA in the first reflector 102, in which the average resistance of the second part BS2 is higher than the average resistance of the first part BS1.

In one example, the high resistance region HRA (the dark gray region in FIG. 14) is an insulating region or a semi-insulating region. Specifically, the high-resistance region HRA is, in one example, an ion implantation region. In one example, the ion implantation region serving as the high resistance region HRA is provided throughout the entirety of the first reflector 102 in the second part BS2. For example, H+, B+, and the like can be given as examples of the ion species in the ion implantation region. The ion concentration of the ion implantation region may be uniform across the entire region, or may be non-uniform (e.g., may have a distribution, such as a gradation, steps, or the like). For example, a suitable value for the ion concentration of the ion implantation region can be calculated on the basis of the foregoing AR.

### Manufacturing Method for Surface-Emitting Laser Array

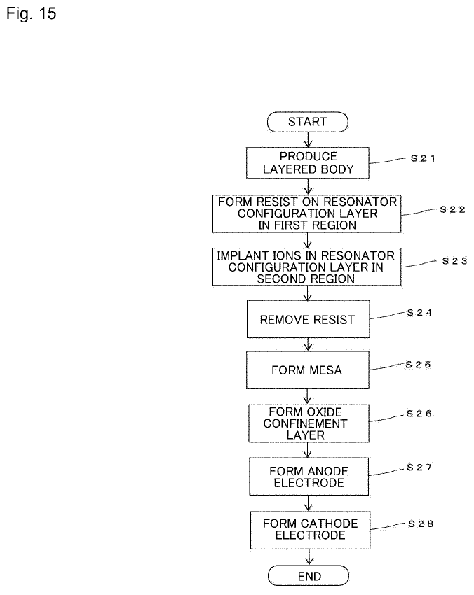

A method for manufacturing the surface-emitting laser array 30 will be described hereinafter with reference to the flowchart in FIG. 15 and the like. FIGS. 16A to 18B are cross-sectional process views corresponding to the cross-section along line 1-1 in FIG. 2. As the overall flow, first, a plurality of surface-emitting laser arrays 30 are produced simultaneously on a single wafer serving as the substrate 101 (called simply the “substrate 101” for convenience hereinafter) through a semiconductor manufacturing method using a semiconductor manufacturing device. Next, the series of the plurality of integrated surface-emitting laser arrays 30 are separated from each other through dicing to obtain a chip-shaped surface-emitting laser array 30. In the following descriptions, for convenience, the region corresponding to the first region A1 will be called the “first region A1”, and the region corresponding to the second region A2 will be called the “second region A2”.

In the first step, step S21, a layered body is produced (see FIG. 7A). Specifically, a layered body is produced by layering the first reflector 102, the active layer 103, the second reflector 104 having an oxidized layer 105S (e.g., an AlAs layer or an AlGaAs layer) serving as the material of the oxide confinement layer 105, and the contact layer 106 in that order on the substrate 101 (e.g., an n-GaAs substrate) serving as a growth substrate, through an epitaxial crystal growth method such as Metal Organic Chemical Vapor Deposition (MOCVD), for example. At this time, a methyl-based organic metal gas such as trimethyl aluminum (TMAI), trimethyl gallium (TMGa), trimethyl indium (TMIn), or the like, and arsine (AsH₃) gas, are used as the materials for the compound semiconductor, for example; disilane (Si₂H₆) is used as the material for donor impurities, for example; and carbon tetrachloride (CBr₄) is used as the material for acceptor impurities, for example.

In the next step, step S22, a resist r is formed on a resonator configuration layer (a layer including the first reflector 102, the active layer 103, the oxidized layer 105S, the second reflector 104, and the contact layer 106; the same applies hereinafter) in the first region A1 (see FIG. 16A). Specifically, through photolithography, a rectangular resist r is formed on the top surface of the resonator configuration layer (the surface on the side where the contact layer 106 is located) in the first region A1.

In the next step, step S23, ion implantation is performed on the resonator configuration layer in the second region A2 (see FIG. 16B). Specifically, using the resist r as a mask, ions are implanted from the top surface side of the resonator configuration layer in the second region A2 to a predetermined concentration (e.g., a concentration corresponding to the foregoing AR) over the entirety of the resonator configuration layer.

In the next step, step S24, the resist r is removed (see FIG. 16C). Specifically, the resist r is removed by wet etching or the like, for example.

In the next step, step S25, a mesa is formed (see FIG. 17A). Specifically, using photolithography, a resist is formed covering the location where the mesa of each surface-emitting laser 100 is to be formed on the layered body, and the layered body is etched through dry etching or wet etching using the resist as a mask. The etching at this time is performed to a depth that ensures the etching bottom surface is located within the first reflector 102, for example. A mesa in which the side surfaces of the oxidized layer 105S are exposed is formed as a result. The resist is then removed.

In the next step, step S26, an oxide confinement layer is formed (see FIG. 17B). Specifically, each mesa is exposed to a high-temperature water vapor atmosphere, and the oxidized layer 105S is oxidized from the side surfaces to form the oxide confinement layer 105 in which the non-oxide region 105a is surrounded by the oxide region 105b.

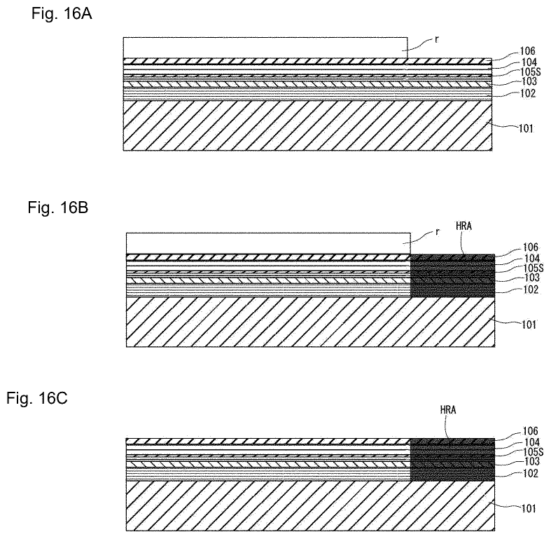

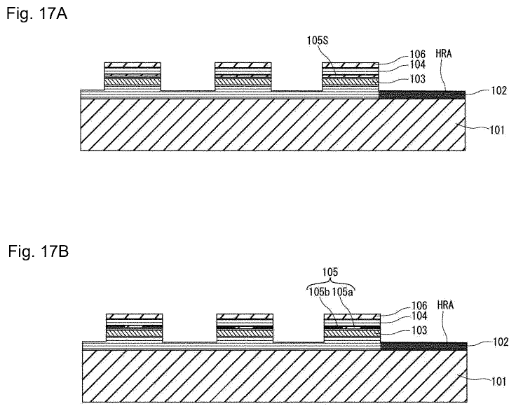

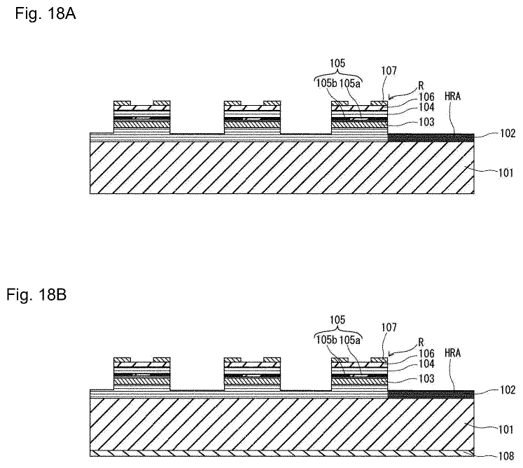

In the next step, step S27, the anode electrode 107 is formed (see FIG. 18A). Specifically, the ring-shaped anode electrode 107 is formed at the top of each mesa through a lift-off method, for example. At this time, vapor deposition, sputtering, or the like is used for the deposition of the electrode material, for example.

In the final step, step S18, the cathode electrode 108 is formed (see FIG. 18B). Specifically, the cathode electrode 108 is formed in a solid shape on the rear surface of the substrate 101 through a lift-off method, for example. At this time, vapor deposition, sputtering, or the like is used for the deposition of the electrode material, for example.

### Effects of Surface-Emitting Laser Array

According to the surface-emitting laser array 30 of the third embodiment, the same effects as the surface-emitting laser array 10 according to the first embodiment can be achieved.

### 4. Surface-Emitting Laser Array According to Fourth Embodiment of Present Technique

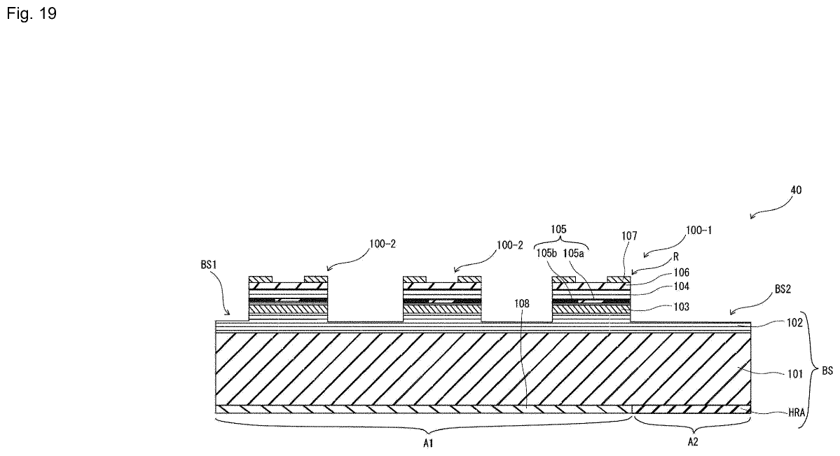

FIG. 19 is a cross-sectional view of a surface-emitting laser array 40 according to a fourth embodiment of the present technique. As illustrated in FIG. 19, the surface-emitting laser array 40 has the same configuration as the surface-emitting laser array 20 according to the second embodiment, except that the second part BS2 has the high-resistance region HRA, in which the average resistance of the second part BS2 is higher than the average resistance of the first part BS1, on the rear surface (the bottom surface; the surface on the opposite side from the resonator R side) side of the substrate 101.

In the surface-emitting laser array 40, the cathode electrode 108 is provided only on the rear surface of the substrate 101 in the first part BS1, and the high-resistance region HRA is provided in a frame shape on the rear surface of the substrate 101 in the second part BS2 so as to surround the cathode electrode 108.

The high-resistance region HRA is preferably an insulating region. In one example, the high-resistance region HRA is an insulating film. In one example, the insulating film serving as the high resistance region HRA is constituted by a dielectric such as SiO₂, SiN, SiON, or the like. A suitable value for the electrical resistance of the dielectric can be calculated on the basis of the foregoing AR.

The surface-emitting laser array 40 can be manufactured by the same manufacturing method as the manufacturing method of the surface-emitting laser array 10 according to the first embodiment, except that impurities are not implanted in the substrate 101 in the first part BS1, the cathode electrode 108 is provided on the rear surface of the substrate 101 in the first part BS1, and the insulating film serving as the high resistance region HRA is provided on the rear surface of the substrate 101 in the second part BS2.

According to the surface-emitting laser array 40 of the fourth embodiment, the same effects as the surface-emitting laser array 10 according to the first embodiment can be achieved.

### 5. Surface-Emitting Laser Array According to Fifth Embodiment of Present Technique

### Configuration of Surface-Emitting Laser Array

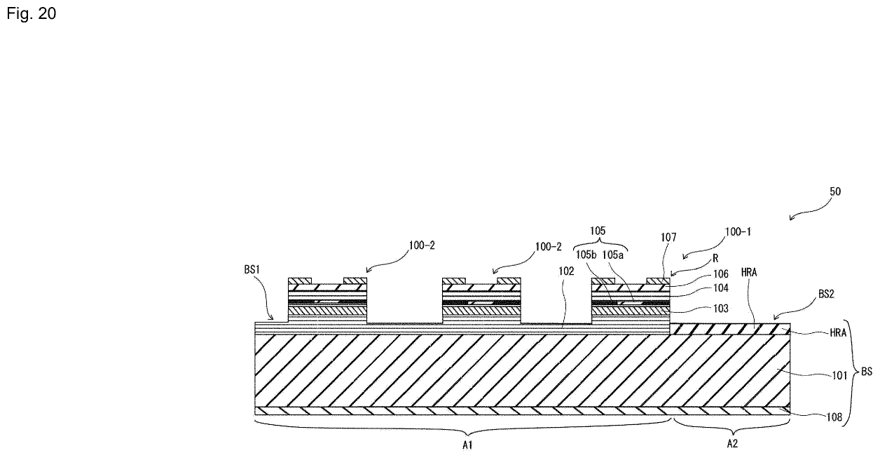

FIG. 20 is a cross-sectional view of a surface-emitting laser array 50 according to a fifth embodiment of the present technique. As illustrated in FIG. 20, the surface-emitting laser array 50 has the same configuration as the surface-emitting laser array 40 according to the fourth embodiment, except that the second part BS2 has the high-resistance region HRA, in which the average resistance of the second part BS2 is higher than the average resistance of the first part BS1, on the top surface side (the surface on the resonator R side) of the substrate 101.

In the surface-emitting laser array 50, the first reflector 102 is provided only in the first part BS1, and the high-resistance region HRA is provided in a frame shape on the top surface of the substrate 101 in the second part BS2 so as to surround the first part BS1.

The high-resistance region HRA is preferably an insulating region. In one example, the high-resistance region HRA is an insulating film. In one example, the insulating film serving as the high resistance region HRA is constituted by a dielectric such as SiO₂, SiN, SiON, or the like. A suitable value for the electrical resistance of the dielectric can be calculated on the basis of the foregoing AR.

### Manufacturing Method for Surface-Emitting Laser Array

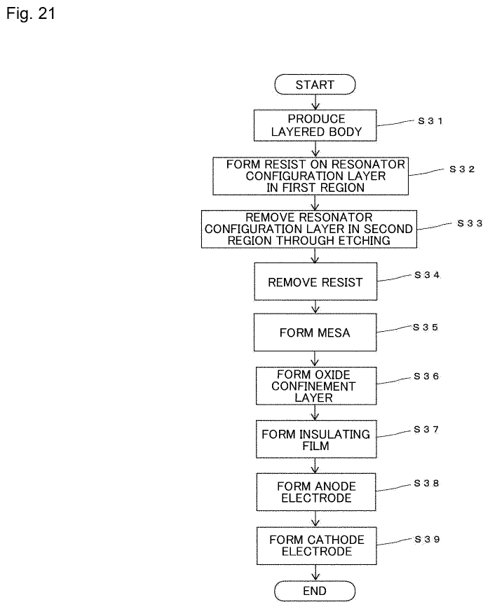

A method for manufacturing the surface-emitting laser array 50 will be described hereinafter with reference to the flowchart in FIG. 21 and the like. FIGS. 22A to 24B are cross-sectional process views corresponding to the cross-section along line 1-1 in FIG. 2. As the overall flow, first, a plurality of surface-emitting laser arrays 50 are produced simultaneously on a single wafer serving as the substrate 101 (called simply the “substrate 101” for convenience hereinafter) through a semiconductor manufacturing method using a semiconductor manufacturing device. Next, the series of the plurality of integrated surface-emitting laser arrays 50 are separated from each other through dicing to obtain a chip-shaped surface-emitting laser array 50. In the following descriptions, for convenience, the region corresponding to the first region A1 will be called the “first region A1”, and the region corresponding to the second region A2 will be called the “second region A2”.

In the first step, step S31, a layered body is produced (see FIG. 7A). Specifically, a layered body is produced by layering the first reflector 102, the active layer 103, the second reflector 104 having an oxidized layer 105S (e.g., an AlAs layer or an AlGaAs layer) serving as the material of the oxide confinement layer 105, and the contact layer 106 in that order on the substrate 101 (e.g., an n-GaAs substrate) serving as a growth substrate, through an epitaxial crystal growth method such as Metal Organic Chemical Vapor Deposition (MOCVD), for example. At this time, a methyl-based organic metal gas such as trimethyl aluminum (TMAI), trimethyl gallium (TMGa), trimethyl indium (TMIn), or the like, and arsine (AsH₃) gas, are used as the materials for the compound semiconductor, for example; disilane (Si₂H₆) is used as the material for donor impurities, for example; and carbon tetrachloride (CBr₄) is used as the material for acceptor impurities, for example.

In the next step, step S32, a resist r is formed on a resonator configuration layer (a layer including the first reflector 102, the active layer 103, the oxidized layer 105S, the second reflector 104, and the contact layer 106; the same applies hereinafter) in the first region A1 (see FIG. 22A). Specifically, through photolithography, a rectangular resist r is formed on the top surface of the resonator configuration layer (the surface on the side where the contact layer 106 is located) in the first region A1.

In the next step, step S33, the resonator configuration layer in the second region A2 is removed by etching (see FIG. 22B). Specifically, using the resist r as a mask, the resonator configuration layer in the second region A2 is etched through dry etching or wet etching. The etching at this time is performed to a depth that exposes the top surface of the substrate 101.

In the next step, step S34, the resist r is removed (see FIG. 22C). Specifically, the resist r is removed by wet etching or the like, for example.

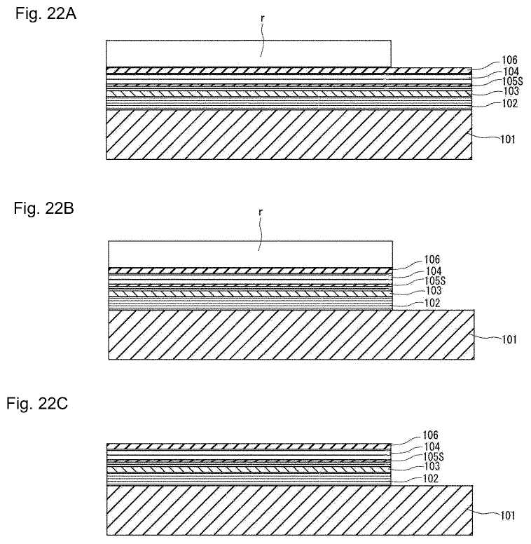

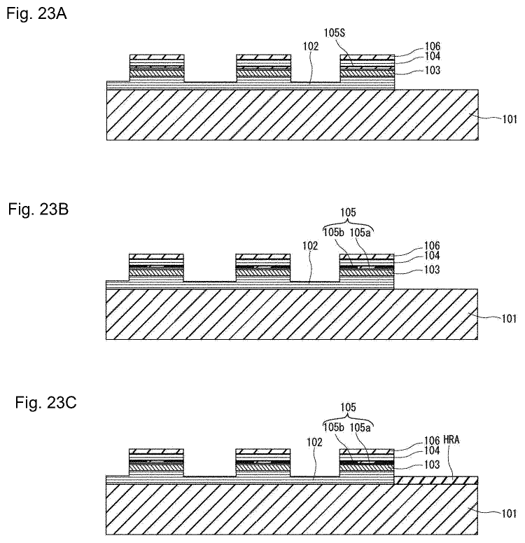

In the next step, step S35, a mesa is formed (see FIG. 23A). Specifically, using photolithography, a resist is formed covering the location where the mesa of each surface-emitting laser 100 is to be formed on the layered body, and the layered body is etched through dry etching or wet etching using the resist as a mask. The etching at this time is performed to a depth that ensures the etching bottom surface is located within the first reflector 102, for example. A mesa in which the side surfaces of the oxidized layer 105S are exposed is formed as a result. The resist is then removed.

In the next step, step S36, the oxide confinement layer 105 is formed (see FIG. 23B). Specifically, each mesa is exposed to a high temperature water vapor atmosphere, and the oxidized layer 105S is oxidized from the side surfaces to form the oxide confinement layer 105 in which the non-oxide region 105a is surrounded by the oxide region 105b.

In the next step, step S37, an insulating film is formed as the high-resistance region HRA (see FIG. 23C). Specifically, after the insulating film is formed on the entire surface, the insulating film covering the first region A1 is removed by photolithography and etching. As a result, an insulating film serving as the high-resistance region HRA is formed in the second region A2.

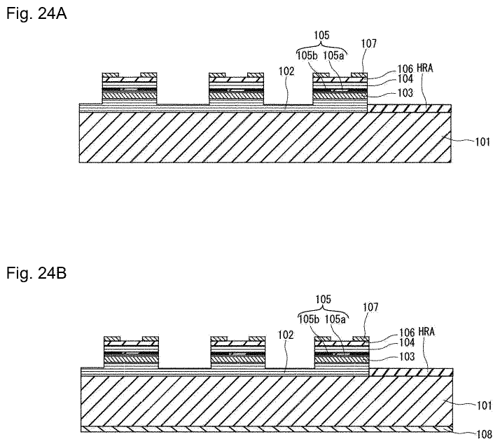

In the next step, step S38, the anode electrode 107 is formed (see FIG. 24A). Specifically, the ring-shaped anode electrode 107 is formed at the top of each mesa through a lift-off method, for example. At this time, vapor deposition, sputtering, or the like is used for the deposition of the electrode material, for example.

In the final step, step S39, the cathode electrode 108 is formed (see FIG. 24B). Specifically, the cathode electrode 108 is formed in a solid shape on the rear surface of the substrate 101 through a lift-off method, for example. At this time, vapor deposition, sputtering, or the like is used for the deposition of the electrode material, for example.

### Effects of Surface-Emitting Laser Array

According to the surface-emitting laser array 50 of the fifth embodiment, the same effects as the surface-emitting laser array 10 according to the first embodiment can be achieved.

### 6. Surface-Emitting Laser Array According to Sixth Embodiment of Present Technique

### Configuration of Surface-Emitting Laser Array

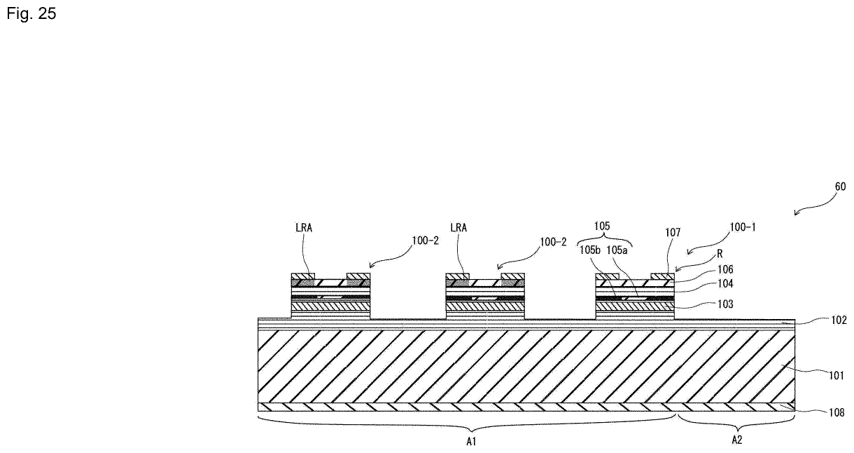

FIG. 25 is a cross-sectional view of a surface-emitting laser array 60 according to a sixth embodiment of the present technique. The surface-emitting laser array 60 has generally the same configuration as the surface-emitting laser array 10 according to the first embodiment, except that in the first region A1, the first surface-emitting laser 100-1, which is the outermost surface-emitting laser 100, has a higher resistance than the second surface-emitting laser 100-2, which is a surface-emitting laser 100 located further inward than the first surface-emitting laser 100-1 in the first region A1.

In the surface-emitting laser array 60, the second surface-emitting laser 100-2 has the low-resistance region LRA in which the first surface-emitting laser 100-1 has a lower resistance than the second surface-emitting laser 100-2.

The low-resistance region LRA is provided in the contact layer 106 of the resonator R of each second surface-emitting laser 100-2. From the viewpoint of suppressing light absorption by the dopant, the low-resistance region LRA is preferably provided only in the region directly below the ring-shaped anode electrode 107 of the contact layer 106. In one example, the low-resistance region LRA is an impurity region.

The low-resistance region LRA is a region doped with p-type impurities, for example. Mg, Zn, P, C, and the like can be given as examples of the p-type impurities (dopant). The doping concentration (impurity concentration) of the low-resistance region LRA is set to be higher than the doping concentration of the p-type impurities in the contact layer 106 of the resonator R of the first surface-emitting laser 100-1, for example. The doping concentration of the low-resistance region LRA may be uniform across the entire region, or may be non-uniform (e.g., may have a distribution, such as a gradation, steps, or the like). A suitable value for the impurity concentration of the low-resistance region LRA can be calculated on the basis of the foregoing AR, for example.

### Manufacturing Method for Surface-Emitting Laser Array

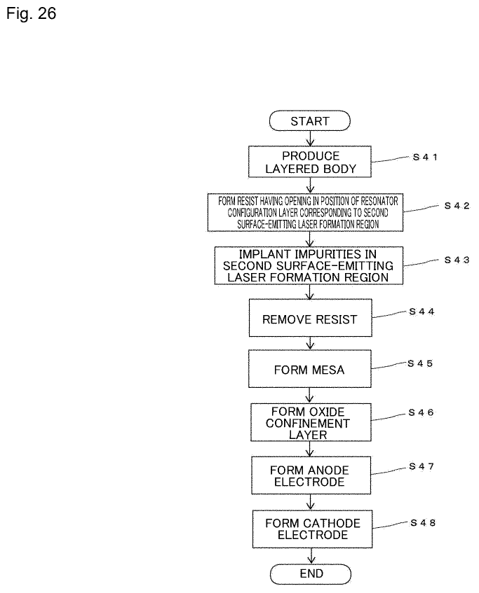

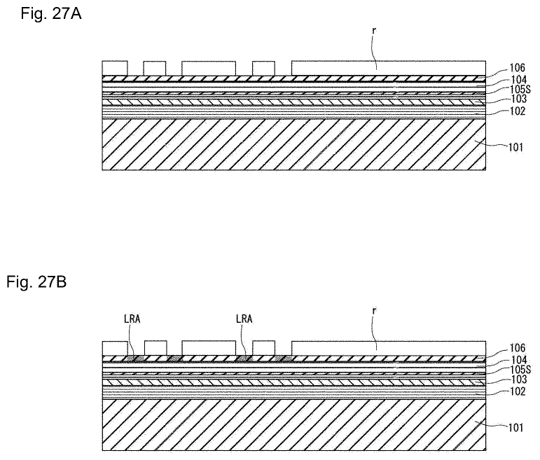

A method for manufacturing the surface-emitting laser array 60 will be described hereinafter with reference to the flowchart in FIG. 26 and the like. FIGS. 27A to 29C are cross-sectional process views corresponding to the cross-section along line 1-1 in FIG. 2. As the overall flow, first, a plurality of surface-emitting laser arrays 60 are produced simultaneously on a single wafer serving as the substrate 101 (called simply the “substrate 101” for convenience hereinafter) through a semiconductor manufacturing method using a semiconductor manufacturing device. Next, the series of the plurality of integrated surface-emitting laser arrays 60 are separated from each other through dicing to obtain a chip-shaped surface-emitting laser array 60. In the following descriptions, for convenience, the region corresponding to the first region A1 will be called the “first region A1”, and the region corresponding to the second region A2 will be called the “second region A2”.

In the first step, step S41, a layered body is produced (see FIG. 7A). Specifically, a layered body is produced by layering the first reflector 102, the active layer 103, the second reflector 104 having an oxidized layer 105S (e.g., an AlAs layer or an AlGaAs layer) serving as the material of the oxide confinement layer 105, and the contact layer 106 in that order on the substrate 101 (e.g., an n-GaAs substrate) serving as a growth substrate, through an epitaxial crystal growth method such as Metal Organic Chemical Vapor Deposition (MOCVD), for example. At this time, a methyl-based organic metal gas such as trimethyl aluminum (TMAI), trimethyl gallium (TMGa), trimethyl indium (TMIn), or the like, and arsine (AsH₃) gas, are used as the materials for the compound semiconductor, for example; disilane (Si₂H₆) is used as the material for donor impurities, for example; and carbon tetrachloride (CBr₄) is used as the material for acceptor impurities, for example.

In the next step, step S42, the resist r is formed having an opening at a position of the resonator configuration layer corresponding to a second surface-emitting laser-forming region (a region where the second surface-emitting laser 100-2 is to be formed) (more specifically, a position corresponding to a region where the anode electrode 107 of the second surface-emitting laser 100-2 is to be formed (see FIG. 27A). Specifically, through photolithography, the resist r is formed on the contact layer 106-side surface of the resonator configuration layer, having an opening at a position corresponding to the second surface-emitting laser-forming region (more specifically, at a position corresponding to a region where the anode electrode 107 of the second surface-emitting laser 100-2 is to be formed).

In the next step, step S43, impurities are implanted in the second surface-emitting laser-forming region (see FIG. 27B). Specifically, using the resist r as a mask, impurities are implanted in the contact layer 106 in the second surface-emitting laser-forming region to achieve a predetermined impurity concentration (e.g., an impurity concentration corresponding to AR).

In the next step, step S44, the resist r is removed (see FIG. 28A). Specifically, the resist r is removed by wet etching or the like, for example.

In the next step, step S45, a mesa is formed (see FIG. 28B). Specifically, using photolithography, a resist is formed covering the location where the mesa of each surface-emitting laser 100 is to be formed on the layered body, and the layered body is etched through dry etching or wet etching using the resist as a mask. The etching at this time is performed to a depth that ensures the etching bottom surface is located within the first reflector 102, for example. A mesa in which the side surfaces of the oxidized layer 105S are exposed is formed as a result. The resist is then removed.

In the next step, step S46, the oxide confinement layer 105 is formed (see FIG. 29A). Specifically, each mesa is exposed to a high temperature water vapor atmosphere, and the oxidized layer 105S is oxidized from the side surfaces to form the oxide confinement layer 105 in which the non-oxide region 105a is surrounded by the oxide region 105b.

In the next step, step S47, the anode electrode 107 is formed (see FIG. 29B). Specifically, the ring-shaped anode electrode 107 is formed at the top of each mesa through a lift-off method, for example. At this time, vapor deposition, sputtering, or the like is used for the deposition of the electrode material, for example.

In the final step, step S48, the cathode electrode 108 is formed (see FIG. 29C). Specifically, the cathode electrode 108 is formed in a solid shape on the rear surface of the substrate 101 through a lift-off method, for example. At this time, vapor deposition, sputtering, or the like is used for the deposition of the electrode material, for example.

### Effects of Surface-Emitting Laser Array

According to the surface-emitting laser array 60 of the sixth embodiment, the same effects as the surface-emitting laser array 10 according to the first embodiment can be achieved.

### 7. Surface-Emitting Laser Array According to Seventh Embodiment of Present Technique

### Configuration of Surface-Emitting Laser Array

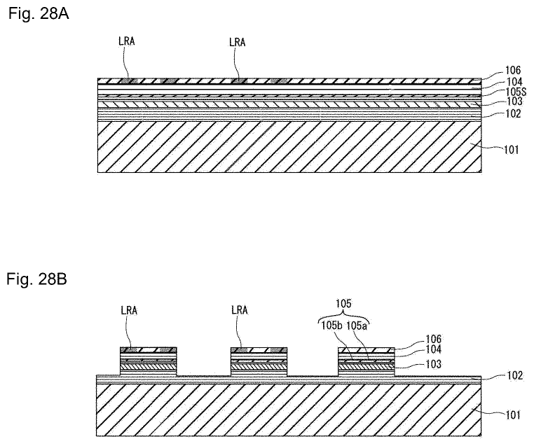

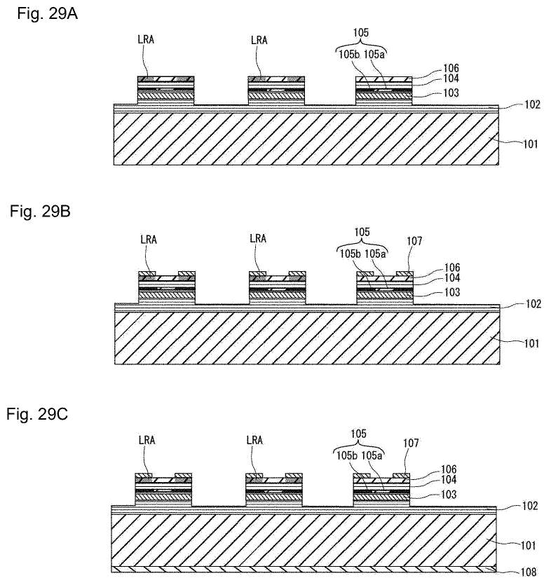

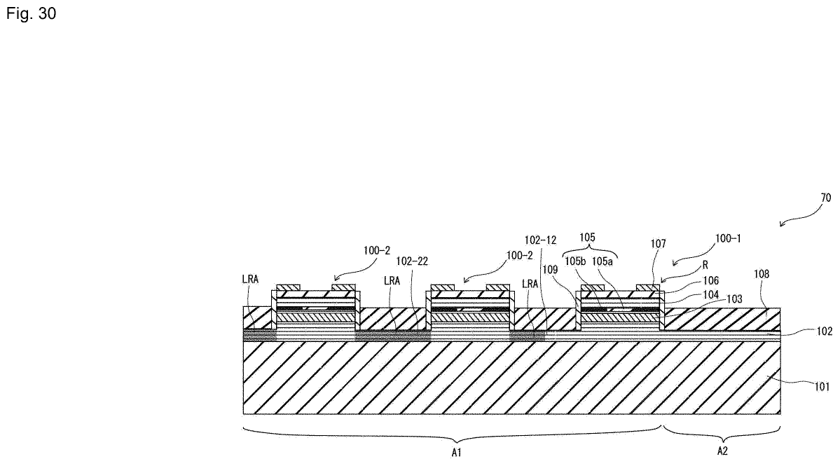

FIG. 30 is a cross-sectional view of a surface-emitting laser array 70 according to a seventh embodiment of the present technique. As illustrated in FIG. 30, in the surface-emitting laser array 70 too, at least a part of the resonator R in two adjacent ones of the surface-emitting lasers 100, in the layering direction of the first structure (e.g., a bottom part of the first reflector 102), is continuous through a continuous part (a bottom part of the first reflector 102). The low-resistance region LRA is provided in a continuous part 102-22 between the resonators R of two adjacent ones of the second surface-emitting lasers 100-2 and 100-2, and in a part of the second surface-emitting laser 100-2 in a continuous part 102-12 between the resonators R of adjacent ones of the first and second surface-emitting lasers 100-1 and 100-2. Note that the low-resistance region LRA may be provided only in the continuous part 102-22.

An insulating film 109 is provided on the side surfaces of the mesa of each surface-emitting laser 100. A common cathode electrode 108 is provided on each continuous part and on the first reflector 102 in the second region A2. In other words, the surface-emitting laser array 70 has an intra cavity structure in which the anode electrode 107 and the cathode electrode 108 are disposed on the same surface side (the resonator R side) of the substrate 101.

In one example, the low-resistance region LRA is an impurity region. The low-resistance region LRA is a region doped with n-type impurities, for example. Si, Se, Te, and the like can be given as examples of the n-type impurity (dopant). The doping concentration (impurity concentration) of the low-resistance region LRAis set to be higher than the doping concentration of the n-type impurities in the first reflector 102 of the resonator R of the first surface-emitting laser 100-1, for example. The doping concentration of the low-resistance region LRA may be uniform across the entire region, or may be non-uniform (e.g., may have a distribution, such as a gradation, steps, or the like). A suitable value for the impurity concentration of the low-resistance region LRA can be calculated on the basis of the foregoing AR, for example.

### Manufacturing Method for Surface-Emitting Laser Array

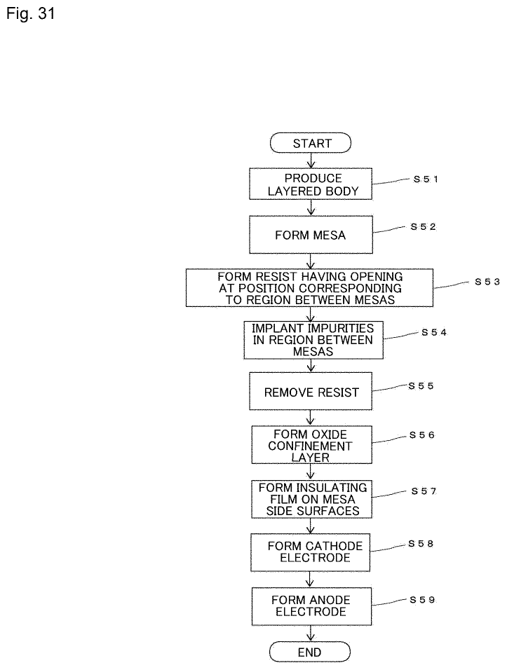

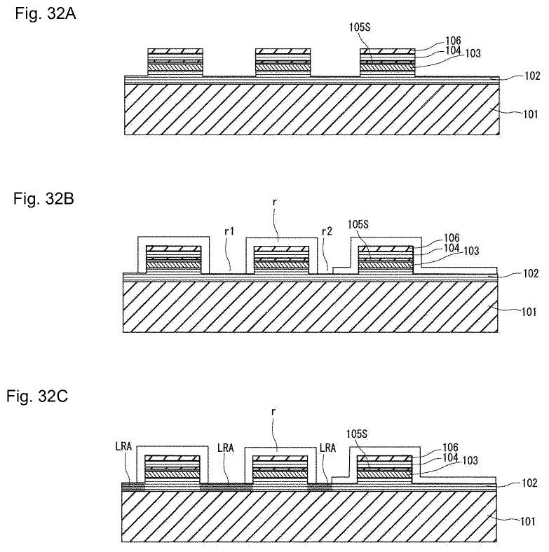

A method for manufacturing the surface-emitting laser array 70 will be described hereinafter with reference to the flowchart in FIG. 31 and the like. FIGS. 32A to 34B are cross-sectional process views corresponding to the cross-section along line 1-1 in FIG. 2. As the overall flow, first, a plurality of surface-emitting laser arrays 70 are produced simultaneously on a single wafer serving as the substrate 101 (called simply the “substrate 101” for convenience hereinafter) through a semiconductor manufacturing method using a semiconductor manufacturing device. Next, the series of the plurality of integrated surface-emitting laser arrays 70 are separated from each other through dicing to obtain a chip-shaped surface-emitting laser array 70. In the following descriptions, for convenience, the region corresponding to the first region A1 will be called the “first region A1”, and the region corresponding to the second region A2 will be called the “second region A2”.

In the first step, step S51, a layered body is produced (see FIG. 7A). Specifically, a layered body is produced by layering the first reflector 102, the active layer 103, the second reflector 104 having an oxidized layer 105S (e.g., an AlAs layer or an AlGaAs layer) serving as the material of the oxide confinement layer 105, and the contact layer 106 in that order on the substrate 101 (e.g., an n-GaAs substrate) serving as a growth substrate, through an epitaxial crystal growth method such as Metal Organic Chemical Vapor Deposition (MOCVD), for example. At this time, a methyl-based organic metal gas such as trimethyl aluminum (TMAI), trimethyl gallium (TMGa), trimethyl indium (TMIn), or the like, and arsine (AsH₃) gas, are used as the materials for the compound semiconductor, for example; disilane (Si₂H₆) is used as the material for donor impurities, for example; and carbon tetrachloride (CBr₄) is used as the material for acceptor impurities, for example.

In the next step, step S52, a mesa is formed (see FIG. 32A). Specifically, using photolithography, a resist is formed covering the location where the mesa of each surface-emitting laser 100 is to be formed on the layered body, and the layered body is etched through dry etching or wet etching using the resist as a mask. The etching at this time is performed to a depth that ensures the etching bottom surface is located within the first reflector 102, for example. A mesa in which the side surfaces of the oxidized layer 105S are exposed is formed as a result. The resist is then removed.

In the next step, step S53, the resist r is formed having an opening at a position corresponding to the region between the mesas (see FIG. 32B). Specifically, a resist r having an opening r1 in a region between the mesas of two adjacent second surface-emitting lasers 100-2 and 100-2, and having an opening r2 in a region on the second surface-emitting laser 100-2 side between the mesas of adjacent first and second surface-emitting lasers 100-1 and 100-2, is formed through photolithography.

In the next step, step S54, impurities are implanted in the regions between the mesas (see FIG. 32C). Specifically, using the resist r as a mask (through the openings r1 and r2), impurities are implanted to a predetermined impurity concentration (e.g., an impurity concentration corresponding to AR).

In the next step, step S55, the resist r is removed (see FIG. 33A). Specifically, the resist r is removed by wet etching or the like, for example.

In the next step, step S56, the oxide confinement layer 105 is formed (see FIG. 33B). Specifically, each mesa is exposed to a high-temperature water vapor atmosphere, and the oxidized layer 105S is oxidized from the side surfaces to form the oxide confinement layer 105 in which the non-oxide region 105a is surrounded by the oxide region 105b.

In the next step, step S57, the insulating film 109 is formed on the side surfaces of the mesa (see FIG. 33C). Specifically, photolithography and etching are performed after the insulating film 109 is formed on the entire surface, such that only the insulating film 109 on the mesa side surface remains.

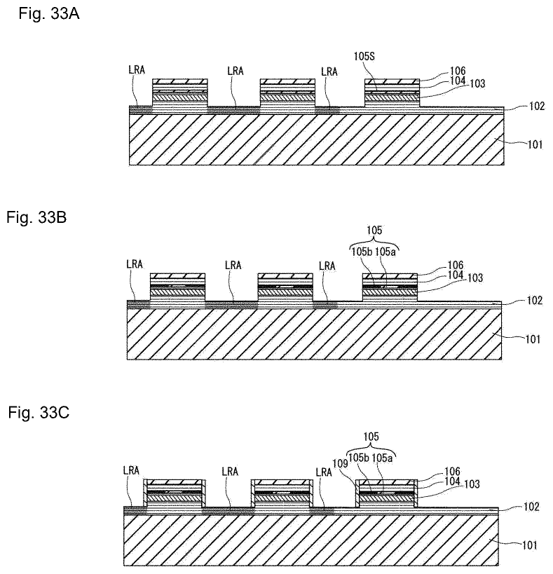

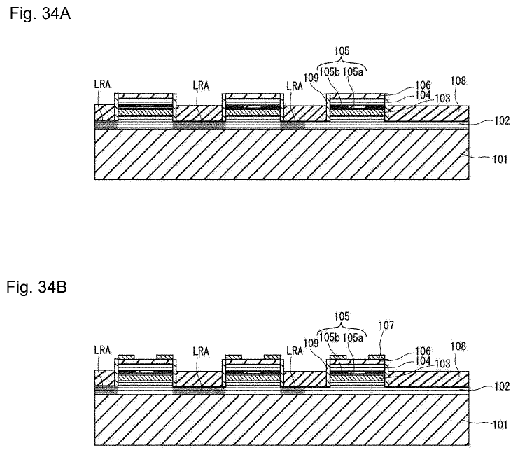

In the next step, step S58, the cathode electrode 108 is formed (see FIG. 34A). Specifically, the cathode electrode 108 is formed on the region around the mesa in the bottom part of the first reflector 102 of each resonator through a lift-off method, for example. At this time, vapor deposition, sputtering, or the like is used for the deposition of the electrode material, for example.

In the next step, step S59, the anode electrode 107 is formed (see FIG. 34B). Specifically, the ring-shaped anode electrode 107 is formed at the top of each mesa through a lift-off method, for example. At this time, vapor deposition, sputtering, or the like is used for the deposition of the electrode material, for example.

### Effects of Surface-Emitting Laser Array

According to the surface-emitting laser array 70 of the seventh embodiment, the same effects as the surface-emitting laser array 10 according to the first embodiment can be achieved.

### 8. Surface-Emitting Laser Array According to Eighth Embodiment of Present Technique

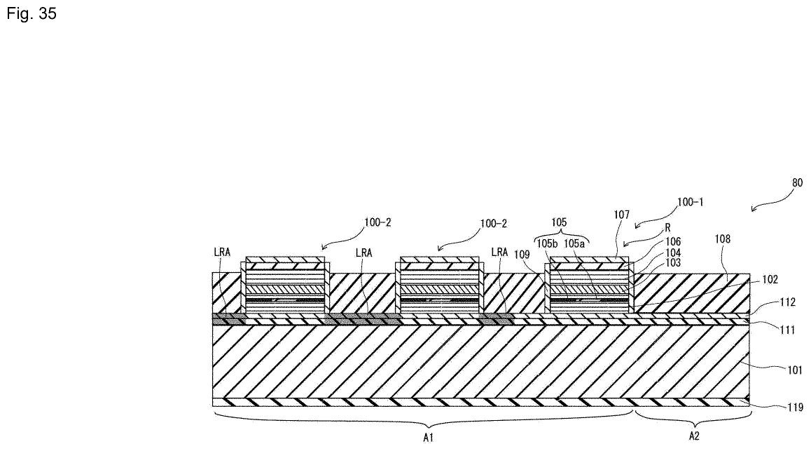

FIG. 35 is a cross-sectional view of a surface-emitting laser array 80 according to an eighth embodiment of the present technique. The surface-emitting laser array 80 is a rear surface-emitting type surface-emitting laser array.

As illustrated in FIG. 35, in the surface-emitting laser array 80, the anode electrode 107 is provided in a solid shape on each mesa. A semi-insulative substrate (e.g., a semi-insulative GaAs substrate) is used for the substrate 101. A contact layer 111 (e.g., an n-GaAs layer) and an etching stop layer 112 (e.g., an InGaP layer) are layered on the substrate 101 in that order. A first structure of the resonator R of each surface-emitting laser 100 includes the contact layer 111 and the etching stop layer 112 in addition to the first reflector 102. The mesa is formed on the etching stop layer 112. An anti-reflection film 119 (AR film) is provided on the rear surface of the substrate 101.

The low-resistance region LRA is provided in a continuous part constituted by the contact layer 111 and the etching stop layer 112 between the resonators R of two adjacent second surface-emitting lasers 100-2 and 100-2 (called the “former”), and in a part of the second surface-emitting laser 100-2 in a continuous part constituted by the contact layer 111 and the etching stop layer 112 between the resonators R of adjacent ones of the first and second surface-emitting lasers 100-1 and 100-2 (called the “latter”). Note that the low-resistance region LRA may be provided only in the former.

An insulating film 109 is provided on the side surfaces of the mesa of each surface-emitting laser 100. A common cathode electrode 108 is provided on the etching stop layer 112 around the mesa of each surface-emitting laser 100.

In one example, the low resistance region LRA is an impurity region. The low-resistance region LRA is a region doped with n-type impurities, for example. Si, Se, Te, and the like can be given as examples of the n-type impurity (dopant). The doping concentration (impurity concentration) of the low-resistance region LRAis set to be higher than the doping concentration of the n-type impurities in the contact layer 111 (e.g., an n-GaAs layer) of the resonator R of the first surface-emitting laser 100-1, for example. The doping concentration of the low-resistance region LRA may be uniform across the entire region, or may be non-uniform (e.g., may have a distribution, such as a gradation, steps, or the like). A suitable value for the impurity concentration of the low-resistance region LRA can be calculated on the basis of the foregoing AR, for example.

The surface-emitting laser array 80 can be manufactured through substantially the same method as the method for manufacturing the surface-emitting laser array 70 according to the seventh embodiment. When manufacturing the surface-emitting laser array 80, etching can be stopped by the etching stop layer 112 during mesa formation, which makes it possible to prevent the contact layer 111 from being etched.

According to the surface-emitting laser array 80 of the eighth embodiment, the same effects as the surface-emitting laser array 10 according to the first embodiment can be achieved.

### 9. Surface-Emitting Laser Array According to Ninth Embodiment of Present Technique

### Configuration of Surface-Emitting Laser Array

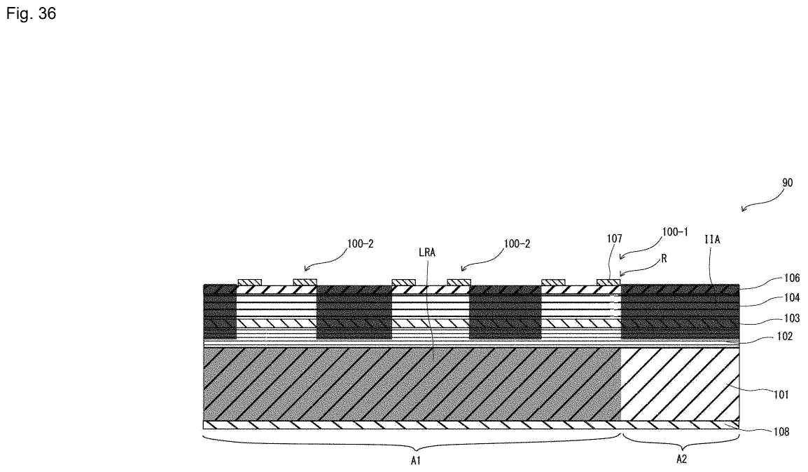

FIG. 36 is a cross-sectional view of a surface-emitting laser array 90 according to a ninth embodiment of the present technique. As illustrated in FIG. 36, the surface-emitting laser array 90 has the same configuration as the surface-emitting laser array 10 according to the first embodiment, except for having a mesa-less structure.

The resonator R of each surface-emitting laser 100 is partitioned by an ion implantation region IIA in plan view. In each surface-emitting laser 100, at least a part (e.g., a top part) of the first reflector 102, the active layer 103, the second reflector 104, and the contact layer 106 are insulated from each other by the ion implantation region IIA.

In the surface-emitting laser array 90, each surface-emitting laser 100 does not have the oxide confinement layer 105. For example, H+, B+, and the like can be given as examples of the ion species in the ion implantation region IIA.

### Manufacturing Method for Surface-Emitting Laser Array

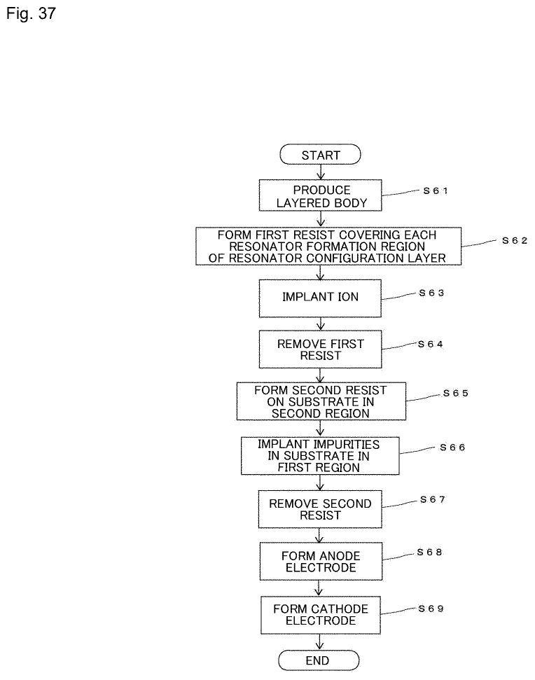

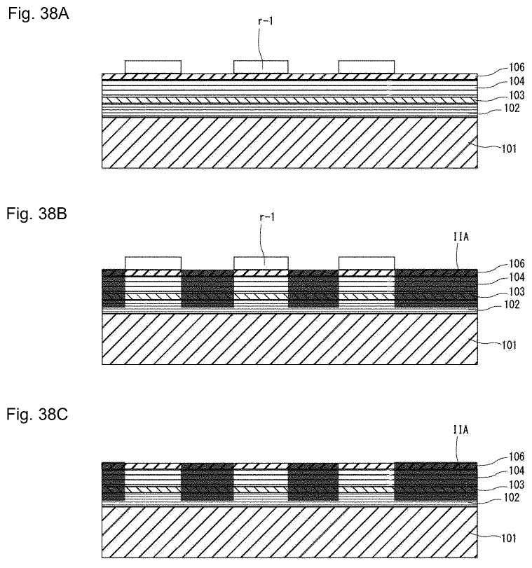

A method for manufacturing the surface-emitting laser array 90 will be described hereinafter with reference to the flowchart in FIG. 37 and the like. FIGS. 38A to 40B are cross-sectional process views corresponding to the cross-section along line 1-1 in FIG. 2. As the overall flow, first, a plurality of surface-emitting laser arrays 90 are produced simultaneously on a single wafer serving as the substrate 101 (called simply the “substrate 101” for convenience hereinafter) through a semiconductor manufacturing method using a semiconductor manufacturing device. Next, the series of the plurality of integrated surface-emitting laser arrays 90 are separated from each other through dicing to obtain a chip-shaped surface-emitting laser array 90. In the following descriptions, for convenience, the region corresponding to the first region A1 will be called the “first region A1”, and the region corresponding to the second region A2 will be called the “second region A2”.

In the first step, step S61, a layered body is produced (see FIG. 7A). Specifically, a layered body is produced by layering the first reflector 102, the active layer 103, the second reflector 104 having an oxidized layer 105S (e.g., an AlAs layer or an AlGaAs layer) serving as the material of the oxide confinement layer 105, and the contact layer 106 in that order on the substrate 101 (e.g., an n-GaAs substrate) serving as a growth substrate, through an epitaxial crystal growth method such as Metal Organic Chemical Vapor Deposition (MOCVD), for example. At this time, a methyl-based organic metal gas such as trimethyl aluminum (TMAI), trimethyl gallium (TMGa), trimethyl indium (TMIn), or the like, and arsine (AsH₃) gas, are used as the materials for the compound semiconductor, for example; disilane (Si₂H₆) is used as the material for donor impurities, for example; and carbon tetrachloride (CBr₄) is used as the material for acceptor impurities, for example.

In the next step, step S62, a first resist r-1 is formed covering each resonator formation region (the region in which each resonator R is to be formed) of the resonator configuration layer (see FIG. 38A). Specifically, the first resist r-1 is formed covering each resonator formation region of the resonator configuration layer through photolithography.

In the next step, step S63, ion implantation is performed (see FIG. 38B). Specifically, the ion implantation is performed using the first resist r-1 as a mask. At this time, the ions are implanted to a depth at which the ions reach the inside of the first reflector 102.

In the next step, step S64, the first resist r-1 is removed (see FIG. 38C). Specifically, the first resist r-1 is removed by wet etching or the like, for example.

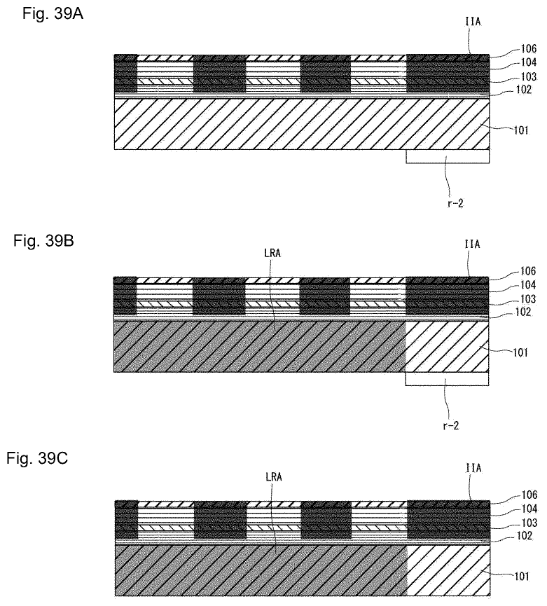

In the next step, step S65, a second resist r-2 is formed on the substrate 101 in the second region A2 (see FIG. 39A). Specifically, the second resist r-2 is formed on the rear surface of the substrate 101 in the second region A2 through photolithography.

In the next step, step S66, impurities are implanted in the substrate 101 in the first region A1 (see FIG. 39B). Specifically, using the second resist r-2 as a mask, impurities are implanted from the rear surface side of the substrate 101 in the first region A1 over the entirety of the substrate 101 to a predetermined concentration (e.g., a concentration corresponding to the foregoing AR).

In the next step, step S67, the second resist r-2 is removed (see FIG. 39C). Specifically, the second resist r-2 is removed by wet etching or the like, for example.

In the next step, step S68, the anode electrode 107 is formed (see FIG. 40A). Specifically, the ring-shaped anode electrode 107 is formed on each resonator through a lift-off method, for example. At this time, vapor deposition, sputtering, or the like is used for the deposition of the electrode material, for example.

In the next step, step S69, the cathode electrode 108 is formed (see FIG. 40B). Specifically, the cathode electrode 108 is formed in a solid shape on the rear surface of the substrate 101 through a lift-off method, for example. At this time, vapor deposition, sputtering, or the like is used for the deposition of the electrode material, for example.

### Effects of Surface-Emitting Laser Array

According to the surface-emitting laser array 90 of the ninth embodiment, substantially the same effects as those of the surface-emitting laser array 10 according to the first embodiment can be achieved.

### 10. Surface-emitting Laser Array According to Tenth Embodiment of Present Technique

### Configuration of Surface-Emitting Laser Array

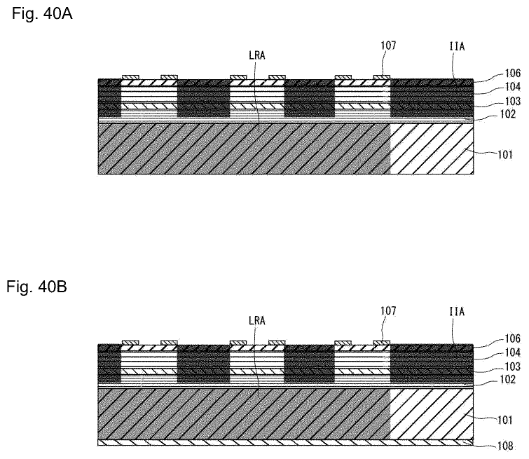

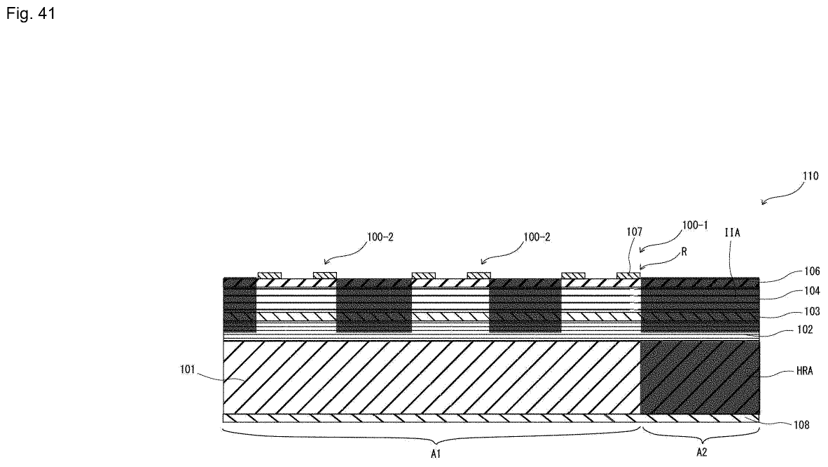

FIG. 41 is a cross-sectional view of a surface-emitting laser array 110 according to a tenth embodiment of the present technique. As illustrated in FIG. 41, the surface-emitting laser array 110 has the same configuration as the surface-emitting laser array 20 according to the second embodiment, except for having a mesa-less structure.

The resonator R of each surface-emitting laser 100 is partitioned by an ion implantation region IIA in plan view. In each surface-emitting laser 100, at least a part (e.g., a top part) of the first reflector 102, the active layer 103, the second reflector 104, and the contact layer 106 are insulated from each other by the ion implantation region IIA.

In the surface-emitting laser array 110, each surface-emitting laser 100 does not have the oxide confinement layer 105. For example, H+, B+, and the like can be given as examples of the ion species in the ion implantation region IIA.

### Manufacturing Method for Surface-Emitting Laser Array

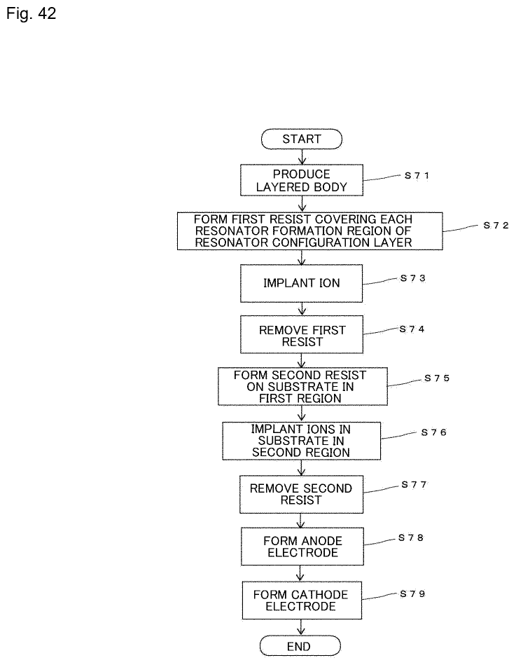

A method for manufacturing the surface-emitting laser array 110 will be described hereinafter with reference to the flowchart in FIG. 42 and the like. FIGS. 43A to 44C are cross-sectional process views corresponding to the cross-section along line 1-1 in FIG. 2. As the overall flow, first, a plurality of surface-emitting laser arrays 110 are produced simultaneously on a single wafer serving as the substrate 101 (called simply the “substrate 101” for convenience hereinafter) through a semiconductor manufacturing method using a semiconductor manufacturing device. Next, the series of the plurality of integrated surface-emitting laser arrays 110 are separated from each other through dicing to obtain a chip-shaped surface-emitting laser array 110. In the following descriptions, for convenience, the region corresponding to the first region A1 will be called the “first region A1”, and the region corresponding to the second region A2 will be called the “second region A2”.

In the first step, step S71, a layered body is produced (see FIG. 7A). Specifically, a layered body is produced by layering the first reflector 102, the active layer 103, the second reflector 104 having an oxidized layer 105S (e.g., an AlAs layer or an AlGaAs layer) serving as the material of the oxide confinement layer 105, and the contact layer 106 in that order on the substrate 101 (e.g., an n-GaAs substrate) serving as a growth substrate, through an epitaxial crystal growth method such as Metal Organic Chemical Vapor Deposition (MOCVD), for example. At this time, a methyl-based organic metal gas such as trimethyl aluminum (TMAI), trimethyl gallium (TMGa), trimethyl indium (TMIn), or the like, and arsine (AsH₃) gas, are used as the materials for the compound semiconductor, for example; disilane (Si₂H₆) is used as the material for donor impurities, for example; and carbon tetrachloride (CBr₄) is used as the material for acceptor impurities, for example.

In the next step, step S72, a first resist r-1 is formed covering each resonator formation region (the region in which each resonator R is to be formed) of the resonator configuration layer (see FIG. 38A). Specifically, the first resist r-1 is formed covering each resonator formation region of the resonator configuration layer through photolithography.

In the next step, step S73, ion implantation is performed (see FIG. 38B). Specifically, the ion implantation is performed using the first resist r-1 as a mask. At this time, the ions are implanted to a depth at which the ions reach the inside of the first reflector 102.

In the next step, step S74, the first resist r-1 is removed (see FIG. 38C). Specifically, the first resist r-1 is removed by wet etching or the like, for example.

In the next step, step S75, a second resist r-2 is formed on the substrate 101 in the first region A1 (see FIG. 43A). Specifically, the second resist r-2 is formed on the rear surface of the substrate 101 in the first region A1 through photolithography.

In the next step, step S76, ion implantation is performed on the substrate 101 in the second region A2 (see FIG. 43B). Specifically, using the second resist r-2 as a mask, ions are implanted from the rear surface side of the substrate 101 in the second region A2 over the entirety of the substrate to a predetermined ion concentration (e.g., a concentration corresponding to the foregoing AR).

In the next step, step S77, the second resist r-2 is removed (see FIG. 44A). Specifically, the second resist r-2 is removed by wet etching or the like, for example.

In the next step, step S78, the anode electrode 107 is formed (see FIG. 44B). Specifically, the ring-shaped anode electrode 107 is formed on each resonator through a lift-off method, for example. At this time, vapor deposition, sputtering, or the like is used for the deposition of the electrode material, for example.

In the next step, step S79, the cathode electrode 108 is formed (see FIG. 44C). Specifically, the cathode electrode 108 is formed in a solid shape on the rear surface of the substrate 101 through a lift-off method, for example. At this time, vapor deposition, sputtering, or the like is used for the deposition of the electrode material, for example.

### Effects of Surface-Emitting Laser Array

According to the surface-emitting laser array 110 of the tenth embodiment, substantially the same effects as those of the surface-emitting laser array 10 according to the first embodiment can be achieved.

### 11. Variations on Present Technique

The surface-emitting laser array according to the present technique is not limited to the foregoing embodiments, and can be changed as appropriate.

For example, the surface-emitting laser array according to each embodiment can be varied in different ways on the condition that the average resistance of the first part BS1 in the base structure BS is lower than the average resistance of the second part BS2, the first surface-emitting laser 100-1 has a higher resistance than the second surface-emitting laser 100-2, and the like, as in the variations described below.

### Surface-Emitting Laser Array According to First to Fourth Variations on First Embodiment

In the surface-emitting laser array 10 according to the first embodiment, the outer edge of the low-resistance region LRA (e.g., the impurity region) need not coincide with the boundaries of the first and second regions A1 and A2.

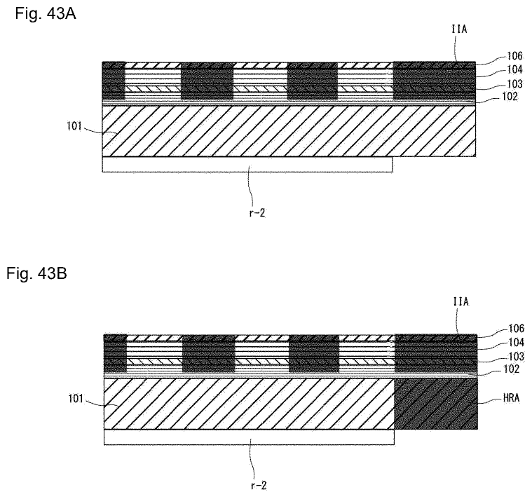

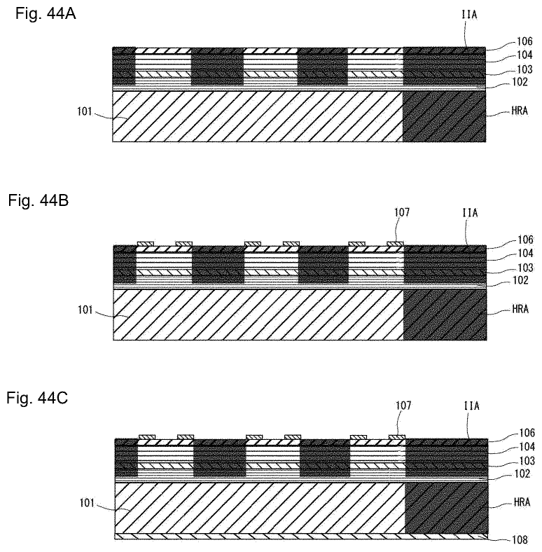

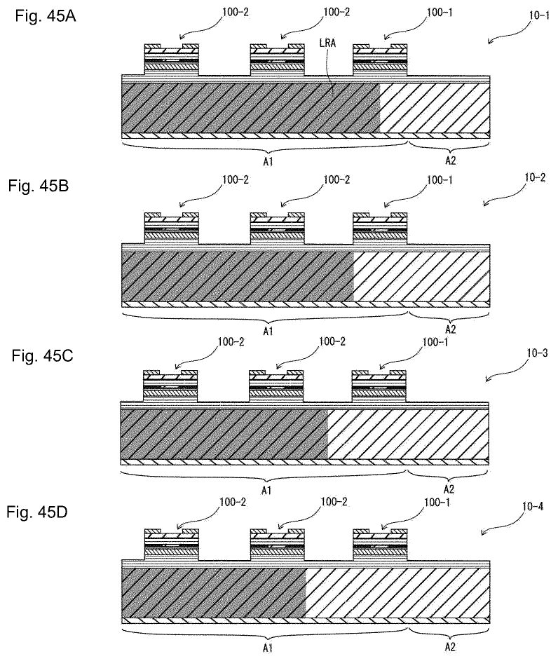

For example, the outer edge of the low-resistance region LRA may be located at a position overlapping with the resonator of the first surface-emitting laser 100-1, as in a surface-emitting laser array 10-1 according to a first variation on the first embodiment, illustrated in FIG. 45A.

For example, the outer edge of the low-resistance region LRA may be located at a position overlapping with an inner edge of the resonator of the first surface-emitting laser 100-1, as in a surface-emitting laser array 10-2 according to a second variation on the first embodiment, illustrated in FIG. 45B.

For example, the outer edge of the low-resistance region LRA may be located between adjacent first and second surface-emitting lasers 100-1 and 100-2, as in a surface-emitting laser array 10-3 according to a third variation on the first embodiment, illustrated in FIG. 45C.

For example, the outer edge of the low resistance region LRA may be located at a position overlapping with an outer edge of the resonator of the second surface-emitting laser 100-2 adjacent to the first surface-emitting laser 100-1, as in a surface-emitting laser array 10-4 according to a fourth variation on the first embodiment, illustrated in FIG. 45D.

### Surface-Emitting Laser Array According to First to Third Variations on Second Embodiment

In the surface-emitting laser array 20 according to the second embodiment, the inner edge of the high-resistance region HRA (e.g., the ion implantation region) need not coincide with the boundaries of the first and second regions A1 and A2, and the outer edge of the high-resistance region HRA (e.g., the ion implantation region) need not coincide with the outer edge of the base structure.

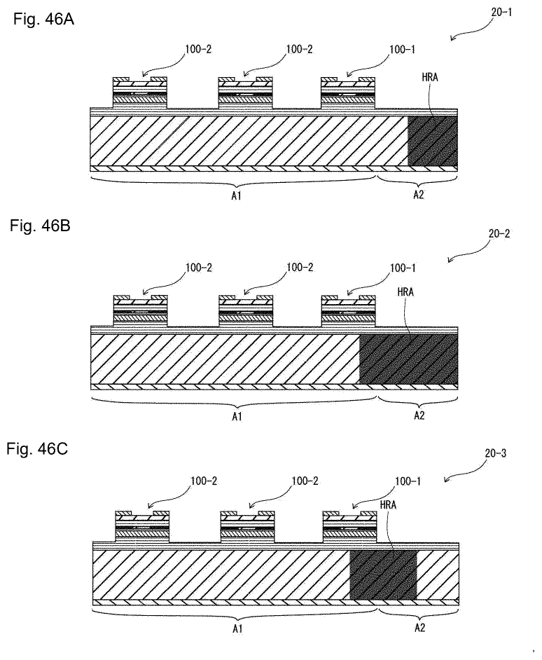

For example, the inner edge of the high-resistance region HRA may be located outside the outer edge of the resonator of the first surface-emitting laser 100-1, as in a surface-emitting laser array 20-1 according to a first variation on the second embodiment, illustrated in FIG. 46A.

For example, the inner edge of the high-resistance region HRA may be located at a position overlapping with the resonator of the first surface-emitting laser 100-1, as in a surface-emitting laser array 20-2 according to a second variation on the second embodiment, illustrated in FIG. 46B.

For example, the inner edge of the high-resistance region HRA may be located at a position overlapping with the resonator of the first surface-emitting laser 100-1, and the outer edge of the high-resistance region HRA may be located between an outer edge of the resonator of the first surface-emitting laser 100-1 and an outer edge of a base structure, as in a surface-emitting laser array 20-3 according to a second variation on the second embodiment, illustrated in FIG. 46C.

### Surface-Emitting Laser Array According to First to Ninth Variations Common to First and Second Embodiments

In the surface-emitting laser arrays 10 and 20 according to the first and second embodiments, both the low-resistance region LRA (e.g., an impurity region) and the high-resistance region HRA (e.g., an ion implantation region) may be provided.

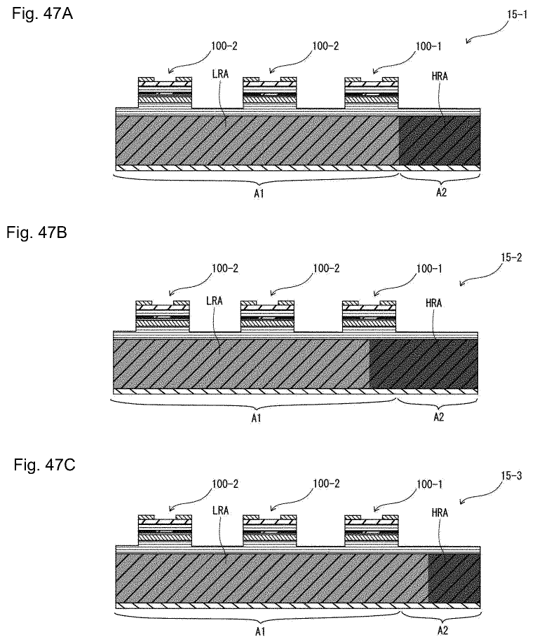

For example, the boundaries of the low-resistance region LRA and the high-resistance region HRA may coincide with the boundaries of the first and second regions A1 and A2, as in a surface-emitting laser array 15-1 according to a first variation common to the first and second embodiments, illustrated in FIG. 47A.

For example, the boundaries of the low-resistance region LRA and the high-resistance region HRA may be located within the first surface-emitting laser 100-1, as in a surface-emitting laser array 15-2 according to a second variation common to the first and second embodiments, illustrated in FIG. 47B.

For example, the boundaries of the low-resistance region LRA and the high-resistance region HRA may be located outside the outer edge of the first surface-emitting laser 100-1, as in a surface-emitting laser array 15-3 according to a third variation common to the first and second embodiments, illustrated in FIG. 47C.

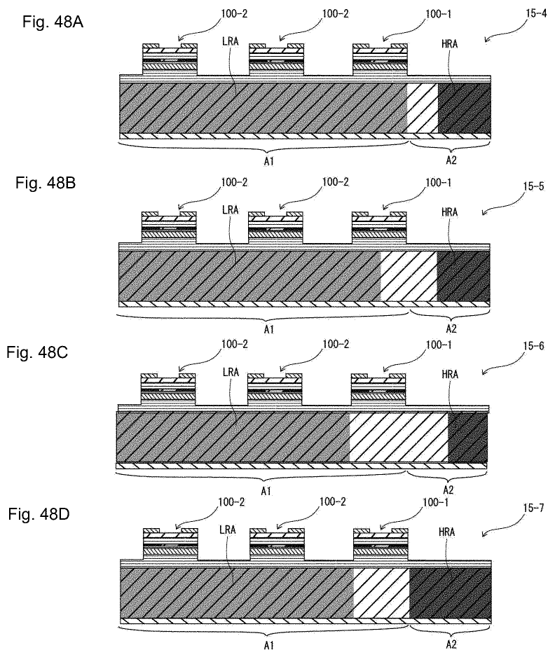

For example, the outer edge of the low-resistance region LRA may overlap with the outer edge of the resonator of the first surface-emitting laser 100-1, and the inner edge of the high-resistance region HRA may be located between the outer edge of the resonator of the first surface-emitting laser 100-1 and the outer edge of the base structure, as in a surface-emitting laser array 15-4 according to a fourth variation common to the first and second embodiments, illustrated in FIG. 48A.

For example, the outer edge of the low resistance region LRA may be located at a position overlapping with the resonator of the first surface-emitting laser 100-1, and the inner edge of the high-resistance region HRA may be located between the outer edge of the resonator of the first surface-emitting laser 100-1 and the outer edge of the base structure, as in a surface-emitting laser array 15-5 according to a fifth variation common to the first and second embodiments, illustrated in FIG. 48B.

For example, the outer edge of the low resistance region LRA may be located at a position overlapping with the inner edge of the resonator of the first surface-emitting laser 100-1, and the inner edge of the high-resistance region HRA may be located between the outer edge of the resonator of the first surface-emitting laser 100-1 and the outer edge of the base structure, as in a surface-emitting laser array 15-6 according to a sixth variation common to the first and second embodiments, illustrated in FIG. 48C.

For example, the outer edge of the low-resistance region LRA may be located at a position overlapping with the inner edge of the resonator of the first surface-emitting laser 100-1, and the inner edge of the high-resistance region HRA may be located at a position overlapping with the outer edge of the resonator of the first surface-emitting laser 100-1, as in a surface-emitting laser array 15-7 according to a seventh variation common to the first and second embodiments, illustrated in FIG. 48D.

For example, the boundaries of the low-resistance region LRA and the high-resistance region HRA may coincide with the boundaries of the first and second regions A1 and A2, and the outer edge of the high-resistance region HRA may be located between the outer edge of the resonator of the first surface-emitting laser 100-1 and the outer edge of the base structure, as in a surface-emitting laser array 15-8 according to an eighth variation common to the first and second embodiments, illustrated in FIG. 49A.

For example, the boundaries of the low-resistance region LRA and the high-resistance region HRA may be located at a position overlapping with the resonator of the first surface-emitting laser 100-1, and the outer edge of the high-resistance region HRA may be located between the outer edge of the resonator of the first surface-emitting laser 100-1 and the outer edge of the base structure, as in a surface-emitting laser array 15-9 according to a ninth variation common to the first and second embodiments, illustrated in FIG. 49B.

### Surface-Emitting Laser Array According to First to Third Variations on Third Embodiment

In the surface-emitting laser array 30 according to the third embodiment, the high-resistance region HRA (e.g., the ion implantation region) may be provided in at least part of at least the first reflector 102 in the second region A2.

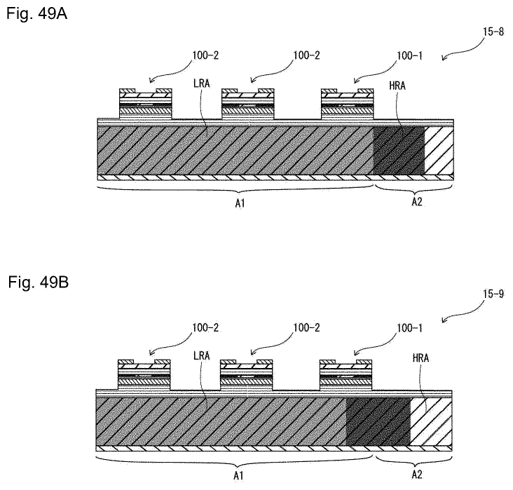

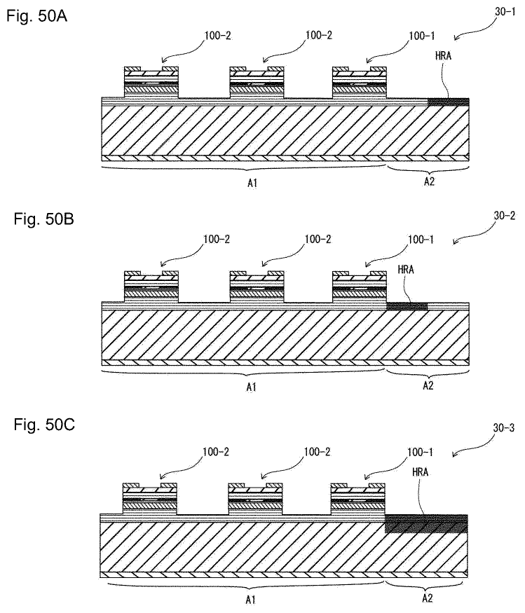

For example, the high-resistance region HRA may be provided only in an outside part of the first reflector 102 in the second region A2, as in a surface-emitting laser array 30-1 according to a first variation on the third embodiment, illustrated in FIG. 50A.

For example, the high-resistance region HRA may be provided only in an inside part of the first reflector 102 in the second region A2, as in a surface-emitting laser array 30-2 according to a second variation on the third embodiment, illustrated in FIG. 50B.

For example, the high-resistance region HRA may be provided across the first reflector 102 and the substrate 101 in the second region A2, as in a surface-emitting laser array 30-3 according to a third variation on the third embodiment, illustrated in FIG. 50C.

### Surface-Emitting Laser Array According to First to Eighth Variations on Sixth Embodiment

In the surface-emitting laser array 60 according to the sixth embodiment, the low-resistance region LRA (impurity region) may be provided in the second surface-emitting laser 100-2, and/or the high-resistance region HRA (ion implantation region) may be provided in the first surface-emitting laser 100-1 or the second region A2.

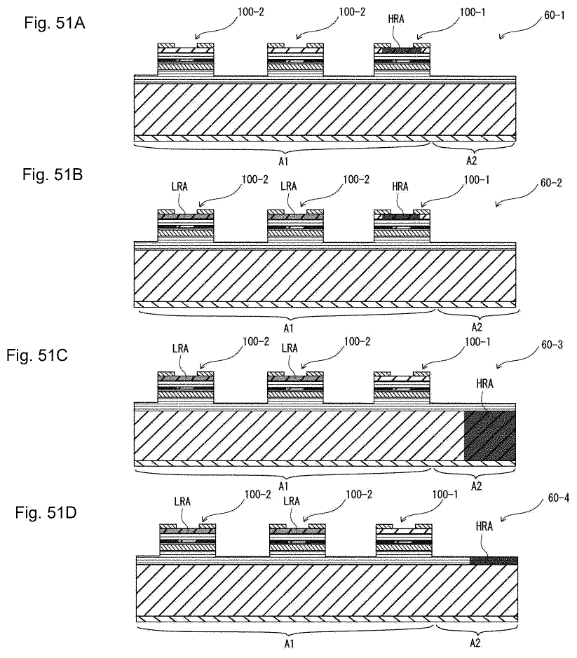

For example, the high resistance region HRA (e.g., an ion implantation region) may be provided in at least part (e.g., a part) of a current path in the contact layer of the first surface-emitting laser 100-1, as in a surface-emitting laser array 60-1 according to a first variation on the sixth embodiment, illustrated in FIG. 51A.

For example, the low-resistance region LRA may be provided in the contact layer of each second surface-emitting laser 100-2, and the high-resistance region HRA (e.g., an ion implantation region) may be provided in the contact layer of the first surface-emitting laser 100-1, as in a surface-emitting laser array 60-2 according to a second variation on the sixth embodiment, illustrated in FIG. 51B.

For example, the low-resistance region LRA may be provided in the contact layer of each second surface-emitting laser 100-2, and the high-resistance region HRA may be provided in the substrate 101 in the second region A2, as in a surface-emitting laser array 60-3 according to a third variation on the sixth embodiment, illustrated in FIG. 51C.

For example, the low-resistance region LRA may be provided in the contact layer of each second surface-emitting laser 100-2, and the high-resistance region HRA may be provided in at least part of the first reflector 102 in the second region A2, as in a surface-emitting laser array 60-4 according to a fourth variation on the sixth embodiment, illustrated in FIG. 51D.

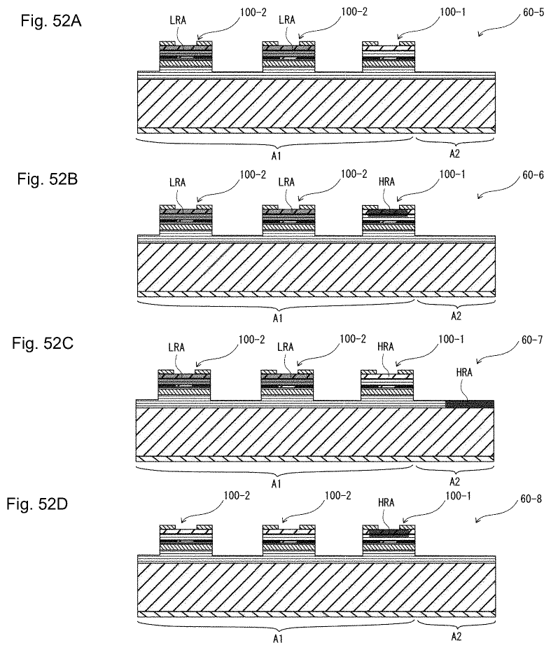

For example, the low-resistance region LRA may be provided in the contact layer and the second reflector of each second surface-emitting laser 100-2, as in a surface-emitting laser array 60-5 according to a fifth variation on the sixth embodiment, illustrated in FIG. 52A.

For example, the low-resistance region LRA (e.g., an impurity region) may be provided in the contact layer and the second reflector of each second surface-emitting laser 100-2, and the high-resistance region HRA (e.g., an ion implantation region) may be provided in at least part (e.g., a part) of the current path in the contact layer and the second reflector of the first surface-emitting laser 100-1, as in a surface-emitting laser array 60-6 according to a sixth variation on the sixth embodiment, illustrated in FIG. 52B.

For example, the low-resistance region LRA may be provided in the contact layer and the second reflector of each second surface-emitting laser 100-2, and the high-resistance region HRA may be provided in at least part of the first reflector in the second region A2, as in a surface-emitting laser array 60-7 according to a seventh variation on the sixth embodiment, illustrated in FIG. 52C.

For example, the high-resistance region HRA (e.g., an ion implantation region) may be provided in at least part (e.g., a part) of a current path in the contact layer and the second reflector of the first surface-emitting laser 100-1, as in a surface-emitting laser array 60-8 according to an eighth variation on the sixth embodiment, illustrated in FIG. 52D.

### Surface-Emitting Laser Array According to Variations on Fourth Embodiment, Fifth Embodiment, and Variation Common to Fourth and Fifth Embodiments

In the surface-emitting laser arrays 40 and 50 according to the fourth and fifth embodiments, the high-resistance region HRA provided in the second region A2 may be an air gap.

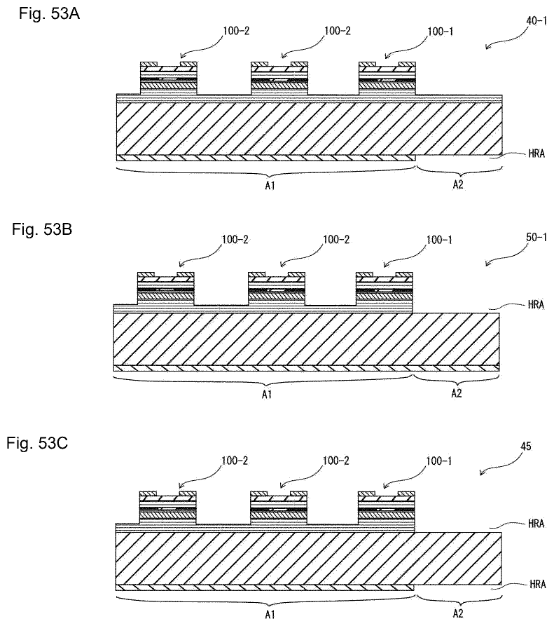

For example, an air gap as the high-resistance region HRA may be provided on the rear surface of the substrate 101 in the second region A2, as in a surface-emitting laser array 40-1 according to a variation on the fourth embodiment, illustrated in FIG. 53A.

For example, an air gap as the high resistance region HRA may be provided on the top surface of the substrate 101 in the second region A2, as in a surface-emitting laser array 50-1 according to a variation on the fifth embodiment, illustrated in FIG. 53B.

For example, an air gap as the high resistance region HRA may be provided on the rear surface and the top surface of the substrate 101 in the second region A2, as in a surface-emitting laser array 45 according to a variation common to the fourth and fifth embodiments, illustrated in FIG. 53C.

### Surface-Emitting Laser Array According to First to Fourth Variations on Seventh Embodiment

In the surface-emitting laser array 70 according to the seventh embodiment, at least the low-resistance region LRA (e.g., an impurity region) may be provided in the continuous part between two adjacent second surface-emitting lasers 100-2 and 100-2, and/or the high-resistance region HRA (e.g., an ion implantation region) may be provided in the second region A2 or the first surface-emitting laser 100-1.

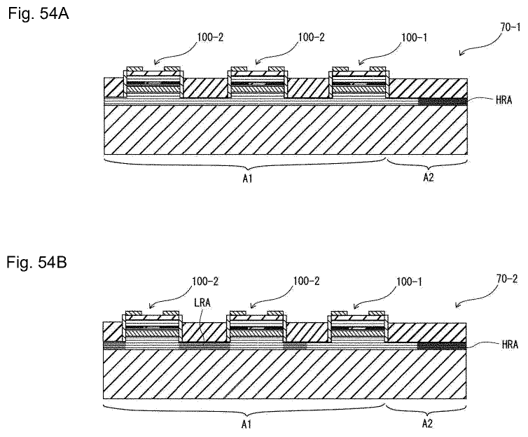

For example, the high-resistance region HRA may be provided in at least part of the first reflector 102 in the second region A2 with respect to the in plane direction, as in a surface-emitting laser array 70-1 according to a first variation on the seventh embodiment, illustrated in FIG. 54A.

For example, the low-resistance region LRA may be provided in the continuous part between the resonators of two adjacent second surface-emitting lasers 100-2 and 100-2 and in a part of the second surface-emitting laser 100-2 in the continuous part between the resonators adjacent ones of the first and second surface-emitting lasers 100-1 and 100-2, and the high-resistance region HRA may be provided in at least part of the first reflector 102 in the second region A2 with respect to the in plane direction, as in a surface-emitting laser array 70-2 according to a second variation on the seventh embodiment, illustrated in FIG. 54B.

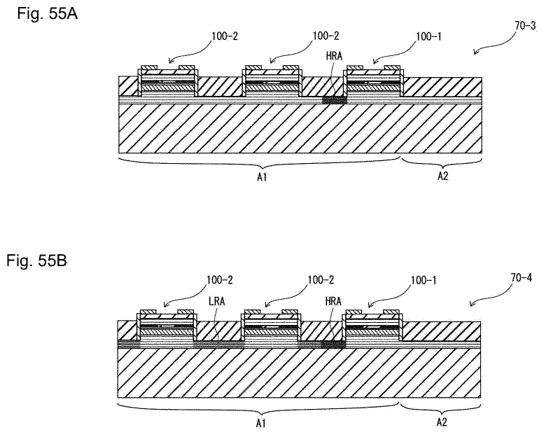

For example, the high-resistance region HRA (e.g., an ion implantation region) may be provided in a part of the first surface-emitting laser 100-1 in the continuous part between the resonators of two adjacent ones of the first and second surface-emitting lasers 100-1 and 100-2, as in a surface-emitting laser array 70-3 according to a third variation on the seventh embodiment, illustrated in FIG. 55A.

For example, the low-resistance region LRA may be provided in the continuous part between the resonators of two adjacent second surface-emitting lasers 100-2 and 100-2 and the part of the second surface-emitting laser 100-2 in the continuous part between the resonators of adjacent ones of the first and second surface-emitting lasers 100-1 and 100-2, and the high-resistance region HRA (e.g., ion implantation region) may be provided in the part of the first surface-emitting laser 100-1 in the continuous part between the resonators of two adjacent ones of the first and second surface-emitting lasers 100-1 and 100-2, as in a surface-emitting laser array 70-4 according to a fourth variation on the seventh embodiment, illustrated in FIG. 55B.

### Surface-Emitting Laser Array According to First and Second Variations on Eighth Embodiment

In the surface-emitting laser array 80 according to the eighth embodiment, at least the low-resistance region LRA (e.g., an impurity region) may be provided in the contact layer (e.g., an n-GaAs layer) and the etching stop layer between two adjacent second surface-emitting lasers 100-2 and 100-2, and/or the high-resistance region HRA (e.g., an ion implantation region) may be provided in the second region A2 or the first surface-emitting laser 100-1.

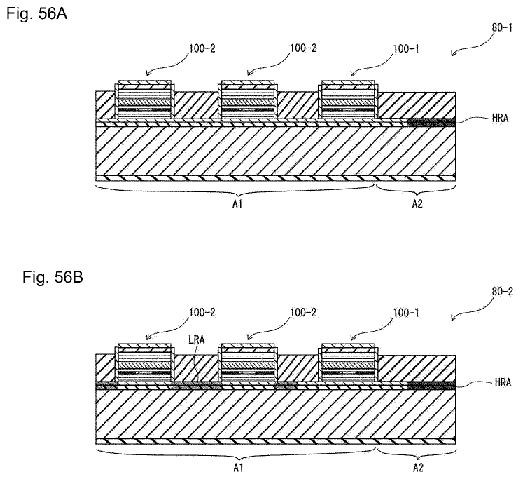

For example, the high-resistance region HRA may be provided in at least a part of the contact layer (e.g., the n-GaAs layer) and the etching stop layer in the second region A2 with respect to the in-plane direction, as in a surface-emitting laser array 80-1 according to a first variation on the eighth embodiment, illustrated in FIG. 56A.

For example, the low-resistance region LRA may be provided in the contact layer (e.g., the n-GaAs layer) and the etching stop layer between the resonators of two adjacent second surface-emitting lasers 100-2 and 100-2 and in a part of the second surface-emitting laser 100-2 in the contact layer (e.g., the n-GaAs layer) and the etching stop layer between the resonators of adjacent ones of the first and second surface-emitting lasers 100-1 and 100-2, and the high resistance region HRA may be provided in at least part of the contact layer and the etching stop layer in the second region A2 with respect to the in-plane direction, as in a surface-emitting laser array 80-2 according to a second variation on the eighth embodiment, illustrated in FIG. 56B.

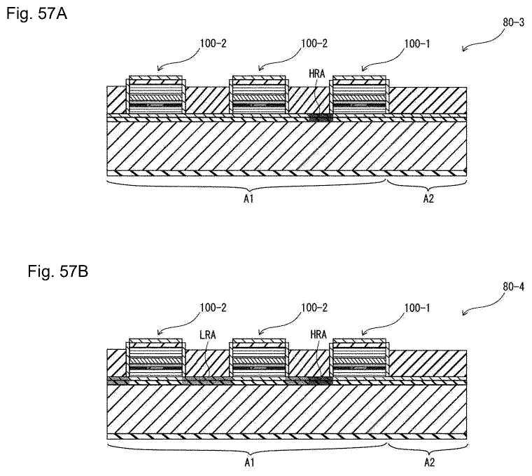

For example, the high-resistance region HRA (e.g., an ion implantation region) may be provided in a part of the first surface-emitting laser 100-1 in the contact layer (e.g., an n-GaAs layer) and the etching stop layer between the resonators of adjacent ones of the first and second surface-emitting lasers 100-1 and 100-2, as in a surface-emitting laser array 80-3 according to a third variation on the eighth embodiment, illustrated in FIG. 57A.

For example, the low-resistance region LRA may be provided in the contact layer (e.g., an n-GaAs layer) and the etching stop layer between the resonators of two adjacent second surface-emitting lasers 100-2 and 100-2 and in a part of the second surface-emitting laser 100-2 in the contact layer (e.g., an n-GaAs layer) and the etching stop layer between the resonators of adjacent ones of the first and second surface-emitting lasers 100-1 and 100-2, and the high-resistance region HRA (e.g., an ion implantation region) may be provided in a part of the first surface-emitting laser 100-1 in the contact layer and the etching stop layer between the resonators of adjacent ones of the first and second surface-emitting lasers 100-1 and 100-2, as in a surface-emitting laser array 80-4 according to a 24th variation on the eighth embodiment illustrated in FIG. 57B.

### Surface-Emitting Laser Array According to First to Third Variations Common to Ninth and Tenth Embodiments

In the surface-emitting laser arrays 90 and 110 according to the ninth and tenth embodiments, the low resistance region LRA (e.g., am impurity region) may be provided in each second surface-emitting laser 100-2 or the first part BS1, and/or the high-resistance region HRA (e.g., an ion implantation region) may be provided in the first surface-emitting laser 100-1 or the second region A2.

For example, the low-resistance region LRA may be provided in the second structure of each second surface-emitting laser 100-2, as in a surface-emitting laser array 95-1 according to a first variation common to the ninth and tenth embodiments, illustrated in FIG. 58A.

For example, the high-resistance region HRA (e.g., an ion implantation region) may be provided in at least part (e.g., a part) of the current path in the second structure of the first surface-emitting laser 100-1, as in a surface-emitting laser array 95-2 according to a second variation common to the ninth and tenth embodiments, illustrated in FIG. 58B.

For example, an insulating film (or an air gap) as the high-resistance region HRA may be provided on the rear surface of the substrate 101 in the second region A2, as in a surface-emitting laser array 95-3 according to a third variation common to the ninth and tenth embodiments, illustrated in FIG. 58C.

In the surface-emitting laser arrays according to the foregoing embodiments and variations, the contact layer 106 is not required.

In the surface-emitting laser arrays according to the foregoing embodiments and variations, a cladding layer (a spacer layer) may be disposed between the active layer 103 and the first reflector 102 and/or between the active layer 103 and the second reflector 104.

For example, the second reflector 104 may be a hybrid mirror in which a semiconductor multilayer reflector and a metal reflector are layered.

Although the foregoing embodiments and variations described GaAs-based surface-emitting laser arrays, the present technique can also be applied to, for example, InP-based and GaN-based surface-emitting laser arrays.

Some of the configurations of the surface-emitting laser arrays in the foregoing embodiments and variations may be combined as long as they do not conflict with each other.

In each of the embodiments and variations described above, the material, conductivity type, thickness, width, numerical value, shape, size, and the like of each layer constituting the surface-emitting laser array can be changed as needed within a scope in which the function as a surface-emitting laser array is maintained.

### 12. Example of Application to Electronic Device

The technique according to the present disclosure (the present technique) can be applied in various products (electronic devices). For example, the technique according to the present disclosure may be realized as a device mounted on any type of moving body, such as an automobile, an electric automobile, a hybrid electric automobile, a motorcycle, a bicycle, a personal mobility device, an airplane, a drone, a ship, or a robot, or in a low energy consumption device (e.g., a smartphone, a smart watch, a tablet, a mouse, or the like).

The surface-emitting laser array according to the present technique can be applied, for example, as a light source for a device that forms or displays images using light (e.g., printers, copiers, projectors, head-mounted displays, heads-up displays, and the like).

### 13. Example of Applying Surface-Emitting Laser Array to Distance Measurement Device

An example of the application of the surface-emitting laser array 10 according to the first embodiment will be described hereinafter.

FIG. 59 illustrates an example of the overall configuration of a distance measurement device 1000 (a range finding device) including the surface-emitting laser array 10 as an example of an electronic device according to the present technique. The distance measurement device 1000 measures the distance to a subject S using the Time Of Flight (TOF) method. The distance measurement device 1000 includes the surface-emitting laser array 10. The distance measurement device 1000 includes, for example, the surface-emitting laser array 10, a light-receiving device 125, lenses 128 and 138, a signal processing unit 145, a control unit 155, a display unit 165, and a storage unit 175.

The light-receiving device 125 receives light emitted from the surface-emitting laser array 10 and reflected by the subject S (an object). In other words, the light-receiving device 125 detects light reflected by the subject S. The lens 128 is a lens for converting light emitted from the surface-emitting laser array 10 into parallel light, and is a collimate lens, for example. The lens 138 is a lens for focusing light reflected by the subject S and guiding that light to the light-receiving device 125, and is a focusing lens, for example.

The signal processing unit 145 is a circuit for generating a signal corresponding to a difference between a signal input from the light-receiving device 125 and a reference signal input from the control unit 155. The control unit 155 is configured including a Time to Digital Converter (TDC), for example. The reference signal may be a signal input from the control unit 155 or may be an output signal of a detection unit that directly detects an output of the surface-emitting laser array 10. The control unit 155 is, for example, a processor that controls the surface-emitting laser array 10, the light receiving device 125, the signal processing unit 145, the display unit 165, and the storage unit 175. The control unit 155 is a circuit that measures the distance to the subject S on the basis of the signal generated by the signal processing unit 145. The control unit 155 generates an image signal for displaying information about the distance to the subject S, and outputs the image signal to the display unit 165. The display unit 165 displays the information about the distance to the subject S on the basis of the image signal input from the control unit 155. The control unit 155 stores the information about the distance to the subject S in the storage unit 175.

In the present application example, any of the surface-emitting laser arrays 10-1, 10-2, 10-3, 10-4, 15-1, 15-2, 15-3, 15-4, 15-5, 15-6, 15-7, 15-8, 15-9, 20, 20-1, 20-2, 20-3, 30, 30-1, 30-2, 30-3, 40, 40-1, 45, 50, 50-1, 60, 60-1, 60-2, 60-3, 60-4, 60-5, 60-6, 60-7, 60-8, 70, 70-1, 70-2, 70-3, 70-4, 80, 80-1, 80-2, 80-3, 80-4, 90, 95-1, 95-2, and 95-3 can also be applied to the distance measurement device 1000 instead of the surface-emitting laser array 10.

### 14. Example of Installing Distance Measurement Device on Moving Body

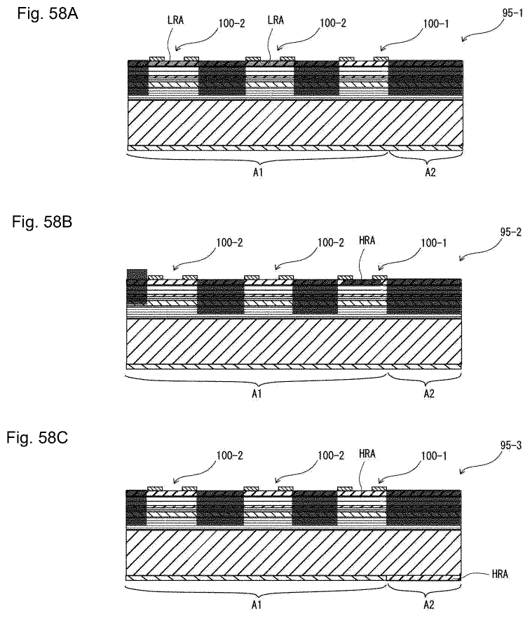

FIG. 60 is a block diagram schematically illustrating an example of the configuration of a vehicle control system, which is an example of a moving body control system to which the technique according to the present disclosure can be applied.

A vehicle control system 12000 includes a plurality of electronic control units connected over a communication network 12001. In the example illustrated in FIG. 60, the vehicle control system 12000 includes a drive system control unit 12010, a body system control unit 12020, a vehicle exterior information detection unit 12030, a vehicle interior information detection unit 12040, and an integrated control unit 12050. In addition, a microcomputer 12051, a sound/image output unit 12052, and an in-vehicle network interface (I/F) 12053 are illustrated as functional configurations of the integrated control unit 12050.

The drive system control unit 12010 controls operations of devices related to a drive system of the vehicle according to various types of programs. For example, the drive system control unit 12010 functions as control devices, such as a driving force generation device for generating driving force for the vehicle, such as an internal combustion engine or a driving motor; a driving force transmission mechanism for transmitting driving force to wheels; a steering mechanism for adjusting a turning angle of the vehicle; a braking device that generates braking force for the vehicle; and the like.

The body system control unit 12020 controls operations of various devices mounted in the vehicle body according to various programs. For example, the body system control unit 12020 functions as control devices for a keyless entry system, a smart key system, power window devices, or various lamps such as headlights, backup lights, brake lights, turn signals, fog lights, and the like. In this case, radio waves emitted from a portable device that substitutes for a key or signals from various switches can be input to the body system control unit 12020. The body system control unit 12020 receives the input of the radio waves or signals and controls door lock devices, power window devices, the lamps, and the like of the vehicle.

The vehicle exterior information detection unit 12030 detects information on the exterior of the vehicle in which the vehicle control system 12000 is installed. For example, a distance measurement device 12031 is connected to the vehicle exterior information detection unit 12030. The distance measurement device 12031 includes the distance measurement device 1000 described above. The vehicle exterior information detection unit 12030 causes the distance measurement device 12031 to measure the distance to an object (the subject S) outside the vehicle and obtains distance data obtained as a result. The vehicle exterior information detection unit 12030 may perform object detection processing for people, cars, obstacles, signs, and the like on the basis of the obtained distance data.

The vehicle interior information detection unit 12040 detects information on the interior of the vehicle. For example, a driver state detection unit 12041 that detects a state of a driver is connected to the vehicle interior information detection unit 12040. The driver state detection unit 12041 includes, for example, a camera that captures an image of the driver, and the vehicle interior information detection unit 12040 may calculate the level of the driver's fatigue or concentration, or may determine whether the driver is dozing, on the basis of detection information input from the driver state detection unit 12041.

For example, the microcomputer 12051 can calculate control target values for the driving force generation device, the steering mechanism, or the braking device on the basis of information on the inside and outside of the vehicle obtained by the vehicle exterior information detection unit 12030 and the vehicle interior information detection unit 12040, and output control commands to the drive system control unit 12010. For example, the microcomputer 12051 can perform coordinated control for the purpose of implementing functions of an Advanced Driver Assistance System (ADAS) including vehicle collision avoidance, impact mitigation, following traveling based on an inter-vehicle distance, cruise control, vehicle collision warnings, and lane departure warnings.

Additionally, the microcomputer 12051 can perform coordinated control for the purpose of automated driving or the like in which autonomous travel is performed without requiring operations of the driver, by controlling the driving force generation device, the steering mechanism, the braking device, or the like on the basis of information about the surroundings of the vehicle, the information being obtained by the vehicle exterior information detection unit 12030 or the vehicle interior information detection unit 12040.

In addition, the microcomputer 12051 can output control commands to the body system control unit 12020 on the basis of the information on the exterior of the vehicle obtained by the vehicle exterior information detection unit 12030. For example, the microcomputer 12051 can perform coordinated control for the purpose of suppressing glare, such as switching from high beams to low beams by controlling the headlights according to the position of a preceding vehicle or an oncoming vehicle detected by the vehicle exterior information detection unit 12030.

The sound/image output unit 12052 transmits an output signal of at least one of sound and an image to an output device capable of visually or audibly providing information to an occupant or to the exterior of the vehicle. In the example illustrated in FIG. 60, an audio speaker 12061, a display unit 12062, and an instrument panel 12063 are illustrated as examples of the output device. The display unit 12062 may include at least one of an on-board display and a heads-up display, for example.

FIG. 61 is a diagram illustrating an example of an installation positions of the distance measurement device 12031.

In FIG. 61, a vehicle 12100 has distance measurement devices 12101, 12102, 12103, 12104, and 12105 as the distance measurement device 12031.

The distance measurement devices 12101, 12102, 12103, 12104, and 12105 are provided at the positions of the front nose, the side-view mirrors, the rear bumper, the trunk door, an upper part of the windshield within the vehicle cabin, and the like of the vehicle 12100, for example. The distance measurement device 12101 provided on the front nose and the distance measurement device 12105 provided in an upper part of the windshield within the vehicle cabin mainly obtain data from in front of the vehicle 12100. The distance measurement devices 12102 and 12103 provided in the side-view mirrors mainly obtain data from the sides of the vehicle 12100. The distance measurement device 12104 provided on the rear bumper or the trunk door mainly obtains data of an area behind the vehicle 12100. The data obtained by the distance measurement devices 12101 and 12105 is mainly used for detecting preceding vehicles, pedestrians, obstacles, traffic signals, traffic signs, and the like.

FIG. 61 illustrates an example of detection ranges of the distance measurement devices 12101 to 12104. A detection range 12111 indicates a detection range by the distance measurement device 12101 provided at the front nose, detection ranges 12112 and 12113 respectively indicate detection ranges by the distance measurement devices 12102 and 12103 provided at the side mirrors, and a detection range 12114 indicates a detection range by the distance measurement device 12104 provided at the rear bumper or the back door.

For example, the microcomputer 12051 can extract, particularly, a closest three-dimensional object on a path through which the vehicle 12100 is traveling, which is a three-dimensional object traveling at a predetermined speed (for example, at least 0 km/h) in substantially the same direction as the vehicle 12100, as a preceding vehicle by obtaining a distance to each three-dimensional object in the detection ranges 12111 to 12114 and temporal changes in the distance (a relative speed with respect to the vehicle 12100) based on the distance data obtained from the distance measurement devices 12101 to 12104. The microcomputer 12051 can also set an inter-vehicle distance to the preceding vehicle to be maintained in advance and perform automatic braking control (including following stop control) and automatic acceleration control (including following start control). It is therefore possible to perform coordinated control for the purpose of, for example, automated driving in which the vehicle travels in an automated manner without requiring the driver to perform operations.

For example, the microcomputer 12051 can classify and extract three-dimensional data regarding three-dimensional objects as two-wheeled vehicles, normal vehicles, large vehicles, pedestrians, and other three-dimensional objects such as electrical poles based on the distance data obtained from the distance measurement devices 12101 to 12104, and can use the three-dimensional data to automatically avoid obstacles. For example, the microcomputer 12051 classifies obstacles around the vehicle 12100 into obstacles visible to the driver of the vehicle 12100 and obstacles which are difficult to see. Then, the microcomputer 12051 determines a collision risk indicating the degree of risk of collision with each obstacle, and when the collision risk is at least a set value and there is a possibility of a collision, an alarm is output to the driver through the audio speaker 12061 or the display unit 12062, forced deceleration or avoidance steering is performed through the drive system control unit 12010, and the like, making it possible to provide driving assistance for collision avoidance.

An example of the moving body control system to which the technique according to the present disclosure can be applied has been described thus far. The technique according to the present disclosure may be applied in the distance measurement device 12031 and the like among the above-described configurations.

In addition, the present technique can also have the following configurations.
(1) A surface-emitting laser array including:
a first region in which a plurality of surface-emitting lasers are disposed in an array; and
a second region surrounding the first region,
wherein among a first part and a second part, which are adjacent in an in-plane direction, of a base structure including a substrate, the first part and the second part, the first part is included in the first region and the second part is included in the second region, and
an average resistance of the first part is lower than an average resistance of the second part.
(2) The surface-emitting laser array according to (1),
wherein the first part has a low-resistance region in which the average resistance of the first part is lower than the average resistance of the second part, and/or the second part has a high-resistance region in which the average resistance of the second part is higher than the average resistance of the first part.
(3) The surface-emitting laser array according to (2),
wherein when the first part has the low-resistance region, the low-resistance region is an impurity region, and
when the second part has the high-resistance region, the high-resistance region is an insulating region or a semi-insulating region.
(4) The surface-emitting laser array according to (2) or (3),
wherein the first part has the low-resistance region, and
the low-resistance region is an impurity region provided within the substrate.
(5) The surface-emitting laser array according to (2) or (3),
wherein the second part has the high-resistance region, and
the high-resistance region is an ion implantation region provided within the substrate.
(6) The surface-emitting laser array according to (2) or (3),
wherein each of the plurality of surface-emitting lasers has a resonator disposed on the substrate,
the second part has the high-resistance region, and
the high-resistance region is provided on a surface of the substrate on a side, where the resonator is located, in the second part.
(7) The surface-emitting laser array according to (6),
wherein the resonator includes:
a first structure disposed on the substrate and including a first reflector;
an active layer disposed on the first structure; and
a second structure disposed on the active layer and including a second reflector, the second part includes at least part of the first structure in a layering direction thereof, provided on a surface of the substrate on a side, where the resonator is located, and
the high-resistance region is an ion implantation region provided within the at least part of the first structure.
(8) The surface-emitting laser array according to (6),
wherein the high resistance region is an insulating region provided on a surface of the substrate on a side, where the resonator is located, in the second part.
(9) The surface-emitting laser array according to (2) or (3),
wherein each of the plurality of surface-emitting lasers has a resonator disposed on the substrate,
an electrode is provided on a surface of the substrate on an opposite side to the side, where the resonator is located, in the first part,
the second part has the high-resistance region, and
the high resistance region is provided on a surface of the substrate on an opposite side to the side, where the resonator is located, in the second part.
(10) The surface-emitting laser array according to (9),
wherein the high-resistance region is an insulating region provided on a surface of the substrate on an opposite side to a side where the resonator is located, in the second part.
(11) A surface-emitting laser array including:
a first region in which a plurality of surface-emitting lasers are disposed in an array; and
a second region surrounding the first region,
wherein a first surface-emitting laser that is the surface-emitting laser outermost in the first region has a higher resistance than a second surface-emitting laser that is the surface-emitting laser further inward than the first surface-emitting laser in the first region.
(12) The surface-emitting laser array according to (11),
wherein the first surface-emitting laser has a high-resistance region in which the first surface-emitting laser has a higher resistance than the second surface-emitting laser, and/or the second surface-emitting laser has a low-resistance region in which the second surface-emitting laser has a lower resistance than the first surface-emitting laser.
(13) The surface-emitting laser array according to (12),
wherein when the first surface-emitting laser has the high-resistance region, the high-resistance region is an insulating region or a semi-insulating region, and when the second surface-emitting laser has the low-resistance region, the low-resistance region is an impurity region.
(14) The surface-emitting laser array according to (12) or (13), wherein
each of the plurality of surface-emitting lasers includes:
a common substrate; and
a resonator disposed on the substrate,
the second surface-emitting laser has the low-resistance region, and
the low-resistance region is provided in the resonator of the second surface-emitting laser.
(15) The surface-emitting laser array according to (14),
wherein the resonator includes:
a first structure disposed on the substrate and including a first reflector;
an active layer disposed on the first structure; and
a second structure disposed on the active layer and including a second reflector, and
the low-resistance region is an impurity region provided within the second structure of the second surface-emitting laser.
(16) The surface-emitting laser array according to (12) or (13), wherein
each of the plurality of surface-emitting lasers includes:
a common substrate; and
a resonator disposed on the substrate,
the resonator includes:
a first structure disposed on the substrate and including a first reflector;
an active layer disposed on the first structure; and
a second structure disposed on the active layer and including a second reflector,
at least part of the resonator of two adjacent ones of the surface-emitting lasers is continuous through a continuous part in a layering direction of the first structure, the second surface-emitting laser has the low-resistance region, and
the low-resistance region is provided at least in the continuous part between the resonators of the two adjacent ones of the second surface-emitting lasers.
(17) The surface-emitting laser array according to (12) or (13), wherein
each of the plurality of surface-emitting lasers includes:
a common substrate; and
a resonator disposed on the substrate,
the first surface-emitting laser has the high-resistance region, and
the high-resistance region is provided in the resonator of the first surface-emitting laser.
(18) The surface-emitting laser array according to (17),
wherein the resonator includes:
a first structure disposed on the substrate and including a first reflector;
an active layer disposed on the first structure; and
a second structure disposed on the active layer and including a second reflector, and
the high resistance region is an ion implantation region provided within the second structure of the first surface-emitting laser.
(19) The surface-emitting laser array according to (12) or (13), wherein
each of the plurality of surface-emitting lasers includes:
a common substrate; and
a resonator disposed on the substrate,
the resonator includes:
a first structure disposed on the substrate and including a first reflector;
an active layer disposed on the first structure; and
a second structure disposed on the active layer and including a second reflector,
at least part of the resonator of two adjacent ones of the surface-emitting lasers is continuous through a continuous part in a layering direction of the first structure, the first surface-emitting laser has the high-resistance region, and
the high resistance region is provided in a part of the first surface-emitting laser, in the continuous part between the resonators of adjacent ones of the first surface-emitting laser and the second surface-emitting laser.
(20) An electronic device including the surface-emitting laser array according to any one of (1) to (19).

### REFERENCE SIGNS LIST

10, 10-1, 10-2, 10-3, 10-4, 15-1, 15-2, 15-3, 15-4, 15-5, 15-6, 15-7, 15-8, 15-9, 20, 20-1,
20-2, 20-3, 30, 30-1, 30-2, 30-3, 40, 40-1, 45, 50, 50-1, 60, 60-1, 60-2, 60-3, 60-4, 60-5,
60-6, 60-7, 60-8, 70, 70-1, 70-2, 70-3, 70-4, 80, 80-1, 80-2, 80-3, 80-4, 90, 95-1, 95-2,
95-3 Surface-emitting laser array
100-1 First surface-emitting laser (surface-emitting laser)
100-2 Second surface-emitting laser (surface-emitting laser)
101 Substrate
102 First reflector
103 Active layer
104 Second reflector
108 Cathode electrode (electrode)
A1 First region
A2 Second region
BS Base structure
BS1 First part
BS2 Second part
LRA Low-resistance region
HRA High-resistance region
R Resonator
ST1 First structure
ST2 Second structure

1. A surface-emitting laser array comprising:
a first region in which a plurality of surface-emitting lasers are disposed in an array; and
a second region surrounding the first region, wherein
among a first part and a second part, which are adjacent in an in-plane direction, of a base structure including a substrate,, the first part is included in the first region and the second part is included in the second region, and
an average resistance of the first part is lower than an average resistance of the second part.

2. The surface-emitting laser array according to claim 1,
wherein the first part has a low-resistance region in which the average resistance of the first part is lower than the average resistance of the second part, and/or the second part has a high-resistance region in which the average resistance of the second part is higher than the average resistance of the first part.

3. The surface-emitting laser array according to claim 2,
wherein when the first part has the low resistance region, the low resistance region is an impurity region, and when the second part has the high-resistance region, the high resistance region is an insulating region or a semi-insulating region.

4. The surface-emitting laser array according to claim 2, wherein
the first part has the low-resistance region, and
the low-resistance region is an impurity region provided within the substrate.

5. The surface-emitting laser array according to claim 2, wherein
the second part has the high resistance region, and
the high-resistance region is an ion implantation region provided within the substrate.

6. The surface-emitting laser array according to claim 2, wherein
each of the plurality of surface-emitting lasers has a resonator disposed on the substrate,
the second part has the high-resistance region, and
the high resistance region is provided on a surface of the substrate on a side, where the resonator is located, in the second part.

7. The surface-emitting laser array according to claim 6,
wherein the resonator includes:
a first structure disposed on the substrate and includes a first reflector;
an active layer disposed on the first structure; and
a second structure disposed on the active layer and includes a second reflector,
wherein the second part includes at least part of the first structure in a layering direction thereof, provided on a surface of the substrate on a side, where the resonator is located, and
the high-resistance region is an ion implantation region that is provided within the at least part of the first structure.

8. The surface-emitting laser array according to claim 6,
wherein the high-resistance region is an insulating region provided on a surface of the substrate on a side, where the resonator is located, in the second part.

9. The surface-emitting laser array according to claim 2,
wherein each of the plurality of surface-emitting lasers has a resonator disposed on the substrate,
an electrode is provided on a surface of the substrate on an opposite side to the side,
where the resonator is located, in the first part,
the second part has the high-resistance region, and
the high-resistance region is provided on a surface of the substrate on an opposite side opposite to the side, where the resonator is located, in the second part.

10. The surface-emitting laser array according to claim 9,
wherein the high-resistance region is an insulating region provided on a surface of the substrate on an opposite side to a side, where the resonator is located, in the second part.

11. A surface-emitting laser array comprising:
a first region in which a plurality of surface-emitting lasers are disposed in an array; and
a second region surrounding the first region,
wherein a first surface-emitting laser that is the surface-emitting laser outermost in the first region has a higher resistance than a second surface-emitting laser that is the surface-emitting laser further inward than the first surface-emitting laser in the first region.

12. The surface-emitting laser array according to claim 11,
wherein the first surface-emitting laser has a high-resistance region in which the first surface-emitting laser has a higher resistance than the second surface-emitting laser, and/or the second surface-emitting laser has a low-resistance region in which the second surface-emitting laser has a lower resistance than the first surface-emitting laser.

13. The surface-emitting laser array according to claim 12, wherein
when the first surface-emitting laser has the high-resistance region, the high-resistance region is an insulating region or a semi-insulating region, and
when the second surface-emitting laser has the low-resistance region, the low-resistance region is an impurity region.

14. The surface-emitting laser array according to claim 12,
wherein each of the plurality of surface-emitting lasers includes:
a common substrate; and
a resonator disposed on the substrate,
the second surface-emitting laser has the low resistance region, and
the low-resistance region is provided in the resonator of the second surface-emitting laser.

15. The surface-emitting laser array according to claim 14, wherein the resonator includes:
a first structure disposed on the substrate and including a first reflector;
an active layer disposed on the first structure; and
a second structure disposed on the active layer and including a second reflector, and
the low-resistance region is an impurity region provided within the second structure of the second surface-emitting laser.

16. The surface-emitting laser array according to claim 12, wherein
each of the plurality of surface-emitting lasers includes:
a common substrate; and
a resonator disposed on the substrate,
the resonator includes:
a first structure disposed on the substrate and including a first reflector;
an active layer disposed on the first structure; and
a second structure disposed on the active layer and including a second reflector,
at least part of the resonator of two adjacent ones of the surface-emitting lasers is continuous through a continuous part in a layering direction of the first structure, the second surface-emitting laser has the low-resistance region, and
the low-resistance region is provided at least in the continuous part between the resonators of the two adjacent ones of the second surface-emitting lasers.

17. The surface-emitting laser array according to claim 12, wherein each of the plurality of surface-emitting lasers includes:
a common substrate; and
a resonator disposed on the substrate,
the first surface-emitting laser has the high resistance region, and
the high-resistance region is provided in the resonator of the first surface-emitting laser.

18. The surface-emitting laser array according to claim 17, wherein the resonator includes:
a first structure disposed on the substrate and including a first reflector;
an active layer disposed on the first structure; and
a second structure disposed on the active layer and including a second reflector, and the high-resistance region is an ion implantation region provided within the second structure of the first surface-emitting laser.

19. The surface-emitting laser array according to claim 12, wherein each of the plurality of surface-emitting lasers includes:
a common substrate; and
a resonator disposed on the substrate,
the resonator includes:
a first structure disposed on the substrate and including a first reflector;
an active layer disposed on the first structure; and
a second structure disposed on the active layer and including a second reflector,
at least part of the resonator of two adjacent ones of the surface-emitting lasers is continuous through a continuous part in a layering direction of the first structure, the second surface-emitting laser has the high-resistance region, and
the high-resistance region is provided in a part of the first surface-emitting laser, in the continuous part between the resonators of adjacent ones of the first surface-emitting laser and the second surface-emitting laser.
